(19) United States
(12) Patent Application Publication
(10) Pub. No.: US 2026/0314071 A1
(43) Pub. Date: Oct. 8, 2026

(54) DISPLAY APPARATUS AND ELECTRONIC DEVICE INCLUDING THE SAME

(71) Applicant: Samsung Display Co., Ltd., Yongin-si (KR)

(72) Inventors: Kwihyun Kim, Yongin-si (KR); Sehyun Lee, Yongin-si (KR)

(21) Appl. No.: 19/570,660

(22) Filed: Mar. 18, 2026

(30) Foreign Application Priority Data
Apr. 7, 2025 (KR) 10-2025-0044899

(51) Int. Cl. H10D 86/40; H10D 86/60; H10H 29/49; H10K 59/131; B60K 35/22; G06F 1/16; H10K 77/10; H10K 102/00

(52) U.S. Cl. CPC H10D 86/443; H10D 86/60; H10H 29/49; H10K 59/131; B60K 35/223; G06F 1/163; G06F 1/1652; H10K 77/111; H10K 2102/311

(57) ABSTRACT

A display apparatus, in which a display area and a non-display area at least partially surrounding the display area are defined, includes a first row including a first-first island portion of the display area, a first connecting portion, and a first-second island portion of the non-display area, which are arranged in a first direction, and a second row disposed on a side of the first row in a second direction intersecting the first direction, the second row including a second-first island portion of the display area, a second connecting portion, and a second-second island portion of the non-display area, which are arranged in the first direction. The first connecting portion and the second-second island portion overlap each other in the second direction, and the first connecting portion has a shape inverted from a shape of the second connecting portion with respect to an axis of symmetry in the first direction.

This application claims priority to Korean Patent Application No. 10-2025-0044899, filed on Apr. 7, 2025, and all the benefits accruing therefrom under 35 U.S.C. §119, the content of which in its entirety is herein incorporated by reference.

### BACKGROUND

### 1. Field

The present disclosure relates to a display apparatus, and more particularly, to a display apparatus and an electronic device including the display apparatus.

### 2. Description of Related Art

In general, as display apparatuses that visually display electrical signals have been developed, various display apparatuses having desired characteristics such as a thin design, light weight, and low power consumption and electronic devices including such display apparatuses have been introduced. For example, research and development have been actively conducted on display apparatuses of various structures such as flexible display apparatuses that may be folded or rolled up and stretchable display apparatuses, and electronic devices including such display apparatuses.

### SUMMARY

As part of efforts to improve the quality of a display apparatus, the resolution thereof has been increased. As the resolution of a display apparatus increases, the integration (or density) of components of the display apparatus (e.g., conductive components such as wirings) may increase, and contact and/or a short-circuit between adjacent components may occur. Thus, a structure capable of preventing, substantially preventing, or at least reducing such contact and/or short circuit may be desired.

According to one or more embodiments, a display apparatus, in which a display area and a non-display area at least partially surrounding the display area are defined, includes a first row including a first first island portion of the display area, a first connecting portion, and a first second island portion of the non-display area, which are arranged in a first direction, and a second row disposed on a side of the first row in a second direction intersecting the first direction, the second row including a second first island portion of the display area, a second connecting portion, and a second second island portion of the non-display area, which are arranged in the first direction, where the first connecting portion and the second second island portion overlap each other in the second direction, where the first connecting portion has a shape inverted from a shape of the second connecting portion with respect to an axis of symmetry in the first direction.

In an embodiment, the display area may have a curved periphery.

In an embodiment, one end of the first connecting portion may be connected to the first first island portion, and an opposing end of the first connecting portion may be connected to the first second island portion, and one end of the second connecting portion may be connected to the second first island portion, and an opposing end of the second connecting portion may be connected to the second second island portion.

In an embodiment, the first connecting portion may include a first first sub-connecting portion connected to the first second island portion, and a plurality of second first sub-connecting portions connected to the first first sub-connecting portion and the first first island portion.

In an embodiment, when viewed along the second direction, the first first sub-connecting portion and the second second island portion may overlap each other.

In an embodiment, the first connecting portion and the second connecting portion may be disposed in the non-display area.

In an embodiment, each of the first connecting portion and the second connecting portion may have a serpentine shape.

In an embodiment, the first first island portion and the second first island portion may have a same shape as each other, and the first second island portion and the second second island portion may have a same shape as each other, where the first first island portion, the second first island portion, the first second island portion, and the second second island portion are rotated by a same angle about a rotational axis in a third direction intersecting the first direction and the second direction.

In an embodiment, the display apparatus may further include a first bridge portion connecting the first first island portion to the second first island portion, and a second bridge portion connecting the first second island portion to the second second island portion.

In an embodiment, the first connecting portion may be connected to one surface of the first second island portion, and the second connecting portion may be connected to one surface of the second second island portion extending in a direction different from the one surface of the first second island portion to which the first connecting portion is connected.

According to one or more embodiments, a display apparatus, in which a display area and a non-display area at least partially surrounding the display area are defined, includes a first row including a first first island portion of the display area, a first connecting portion, and a first second island portion of the non-display area, which are arranged in a first direction, and a second row disposed on a side of the first row in a second direction intersecting the first direction, the second row including a second first island portion of the display area, a second connecting portion, and a second second island portion of the non-display area, which are arranged in the first direction, where the first connecting portion and the second second island portion overlap each other in the second direction, and an area of the second second island portion is less than an area of the first second island portion.

In an embodiment, the display area may have a curved periphery.

In an embodiment, one end of the first connecting portion may be connected to the first first island portion, and an opposing end of the first connecting portion may be connected to the first second island portion, and one end of the second connecting portion may be connected to the second first island portion, and an opposing end of the second connecting portion may be connected to the second second island portion.

In an embodiment, the first connecting portion and the second connecting portion may have a same shape as each other.

In an embodiment, the area of the second second island portion may be in a range from about 50% to about 90% of the area of the first second island portion.

According to one or more embodiments, an electronic device including a display unit includes a display apparatus corresponding to the display unit, where a display area and a non-display area at least partially surrounding the display area are defined in the display apparatus, and strokes disposed under the display apparatus and moving in a vertical direction, where the display apparatus includes a first row including a first first island portion of the display area, a first connecting portion, and a first second island portion of the non-display area, which are arranged in a first direction, and a second row disposed on a side of the first row in a second direction intersecting the first direction, the second row including a second first island portion of the display area, a second connecting portion, and a second second island portion of the non-display area, which are arranged in the first direction, where the first connecting portion and the second second island portion overlap each other in the second direction, and the first connecting portion has a shape inverted from a shape of the second connecting portion with respect to an axis of symmetry in the first direction.

In an embodiment, the electronic device may further include a frame in which the display apparatus and the strokes are accommodated.

In an embodiment, the electronic device may include a wearable electronic device.

In an embodiment, the display apparatus may be three-dimensionally stretchable by the strokes.

In an embodiment, the display unit may have a dome shape in a state where the display apparatus is not three-dimensionally stretched.

### BRIEF DESCRIPTION OF THE DRAWINGS

The above and other features of embodiments of the disclosure will be more apparent from the following description taken in conjunction with the accompanying drawings, in which:

FIG. 1 is a schematic perspective view illustrating a display apparatus, according to an embodiment of the present disclosure;

FIG. 2A is a perspective view illustrating a state where the display apparatus of FIG. 1 is stretched in a first direction;

FIG. 2B is a perspective view illustrating a state where the display apparatus of FIG. 1 is stretched in the first direction;

FIG. 2C is a perspective view illustrating a state where the display apparatus of FIG. 1 is stretched in a second direction;

FIG. 2D is a perspective view illustrating a state where the display apparatus of FIG. 1 is stretched in the first direction and the second direction;

FIG. 2E is a perspective view illustrating a state where the display apparatus of FIG. 1 is stretched in a third direction;

FIG. 3 is a schematic plan view illustrating a display apparatus, according to an embodiment;

FIG. 4A is an enlarged plan view illustrating a portion IV of the display apparatus of FIG. 3, according to an embodiment.;

FIG. 4B is an enlarged plan view illustrating the portion IV of the display apparatus of FIG. 3, according to an embodiment;

FIG. 4C is an enlarged plan view illustrating the portion IV of the display apparatus of FIG. 3, according to an embodiment;

FIG. 4D is an enlarged plan view illustrating a display area of the display apparatus of FIG. 3, according to an embodiment;

FIG. 4E is an enlarged plan view illustrating the portion IV of the display apparatus of FIG. 3, according to an embodiment;

FIG. 5 is a schematic cross-sectional view illustrating a display apparatus, according to an embodiment;

FIGS. 6A, 6B, and 6C are equivalent circuit diagrams illustrating a sub-pixel of a display apparatus, according to various embodiments;

FIG. 7A is a schematic cross-sectional view illustrating a light-emitting element of a display apparatus, according to an embodiment;

FIG. 7B is a schematic cross-sectional view illustrating a light-emitting element of a display apparatus, according to an embodiment;

FIG. 8 is a schematic plan view illustrating a display apparatus, according to an embodiment;

FIG. 9A is an enlarged plan view illustrating a portion VIIIa of the display apparatus of FIG. 8, according to an embodiment;

FIG. 9B is an enlarged plan view illustrating a portion VIIIb of the display apparatus of FIG. 8, according to an embodiment;

FIG. 9C is an enlarged plan view illustrating a portion VIIIc of the display apparatus of FIG. 8, according to an embodiment;

FIG. 9D is an enlarged plan view illustrating a portion VIIId of the display apparatus of FIG. 8, according to an embodiment;

FIG. 9E is an enlarged plan view illustrating a portion VIIIe of the display apparatus of FIG. 8, according to an embodiment;

FIG. 10 is an enlarged plan view illustrating a part of a display apparatus, as a comparative example, to which a characteristic structure of the present disclosure is not applied;

FIG. 11 is an enlarged plan view illustrating the portion VIIId of the display apparatus of FIG. 8, according to an embodiment;

FIG. 12A is a schematic perspective view illustrating an electronic device including a display apparatus, according to an embodiment;

FIG. 12B is a schematic block diagram illustrating an electronic device including a display apparatus, according to an embodiment; and

FIGS. 13A, 13B, 13C, 12D, 13E, 13F, 13G, 13H, 13I are schematic perspective views each illustrating an embodiment of an electronic device including a display apparatus, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below..

Sizes of components in the drawings may be exaggerated or reduced for convenience of explanation. For example, because sizes and thicknesses of components in the drawings are arbitrarily illustrated for convenience of explanation, the present disclosure is not limited thereto.

When a certain embodiment may be implemented differently, a specific process order may be different from the described order. For example, two consecutively described processes may be performed substantially at the same time or may be performed in an order opposite to the described order.

It will be understood that when a layer, region, or component is referred to as being "connected," the layer, the region, or the component may be directly connected or may be indirectly connected with intervening layers, regions, or components therebetween. For example, when layers, regions, or components are referred to as being "electrically connected," the layers, the regions, or the components may be directly electrically connected, or may be indirectly electrically connected with intervening layers, regions, or components therebetween.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings, where the same or corresponding elements are denoted by the same reference numerals throughout and any repetitive detailed description thereof will be omitted or simplified.

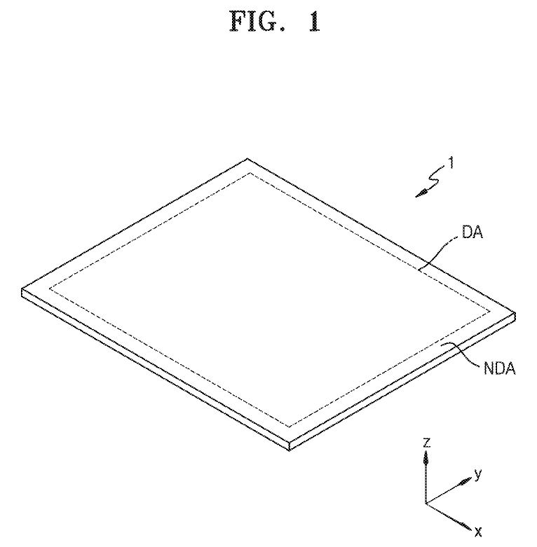

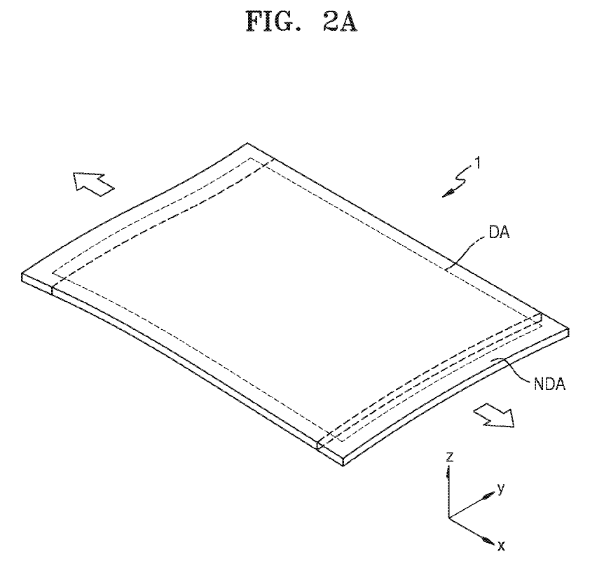

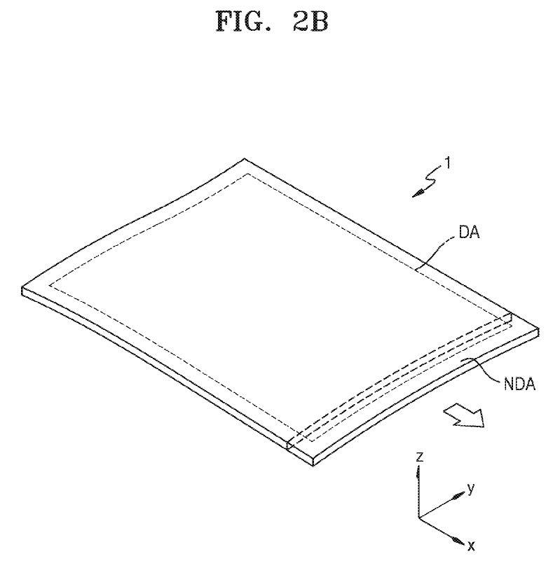

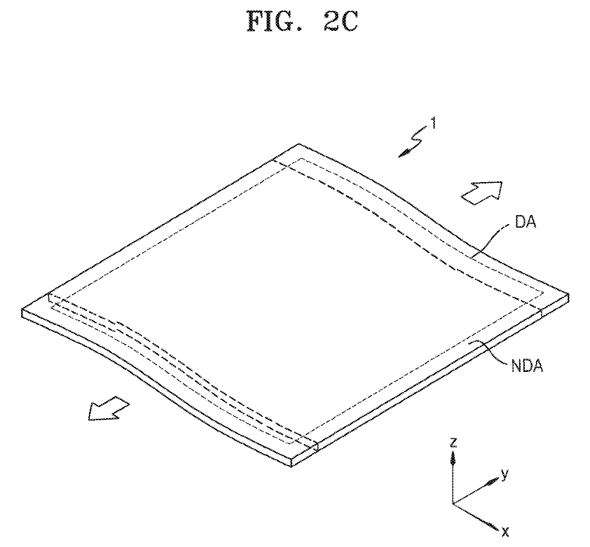

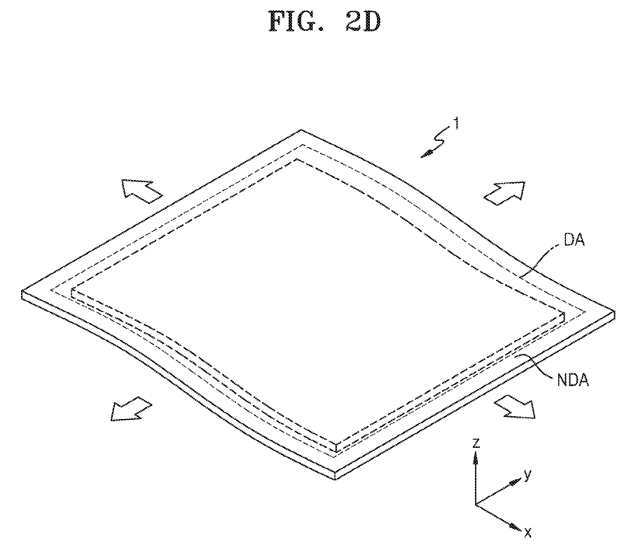

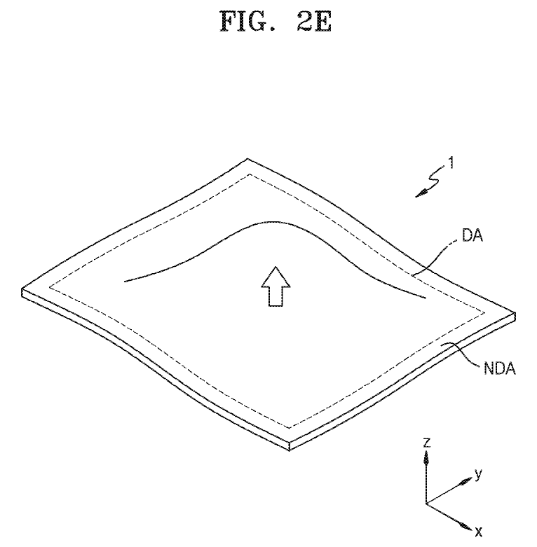

FIG. 1 is a perspective view schematically illustrating a display apparatus, according to an embodiment of the present disclosure. FIGS. 2A and 2B are perspective views illustrating a state where the display apparatus of FIG. 1 is stretched in a first direction. FIG. 2 C is a perspective view illustrating a state where the display apparatus of FIG. 1 is stretched in a second direction. FIG. 2D is a perspective view illustrating a state where the display apparatus of FIG. 1 is stretched in the first direction and the second direction. FIG. 2E is a perspective view illustrating a state where the display apparatus of FIG. 1 is stretched in a third direction.

Referring to FIG. 1, an embodiment of a display apparatus 1 may include a display area DA and a non-display area NDA. The display area DA may include a plurality of pixels. The display apparatus 1 may provide a certain image by using light emitted from the plurality of pixels. The non-display area NDA may be disposed outside the display area DA. The non-display area NDA where pixels are not disposed may entirely surround the display area DA.

In an embodiment, the display apparatus 1 may be stretched or compressed in various directions. The display apparatus 1 may be stretched in the first direction (e.g., a +x direction and/or a -x direction) by an external force applied by a user or an external object. In an embodiment, as shown in FIGS. 2A and 2B, the display area DA and/or the non-display area NDA of the display apparatus 1 may be stretched in the first direction (e.g., the +x direction and/or the -x direction). In an embodiment, for example, the display area DA and/or the non-display area NDA of the display apparatus 1 may be stretched along the +x direction and the -x direction as shown in FIG. 2A, or may be stretched in the +x direction with one side fixed as shown in FIG. 2B.

The display apparatus 1 may be stretched in the second direction (e.g., a +y direction and/or a -y direction) by an external force applied by a user or an external object. In an embodiment, the display area DA and/or the non-display area NDA of the display apparatus 1 may be stretched in the +y direction and the -y direction as shown in FIG. 2C. In another embodiment, the display area DA and/or the non-display area NDA of the display apparatus 1 may be stretched in the +y direction or the -y direction with one side fixed.

The display apparatus 1 may be stretched in a plurality of directions, for example, in the first direction (e.g., the +x direction and/or the -x direction) and the second direction (e.g., the +y direction and/or the -y direction) by an external force applied by a person’s body part or an external object. The display area DA and/or the non-display area NDA of the display apparatus 1 may be stretched in the ±x direction and the ±y direction as shown in FIG. 2D.

The display apparatus 1 may be stretched in the third direction (e.g., a +z direction or a -z direction) by an external force applied by a person’s body part or an external object. Here, the third direction may be a thickness direction of the display apparatus 1. In an embodiment, in FIG. 2E, a part of the display apparatus 1, for example, a portion of the display area DA, protrudes in the +z direction. In another embodiment, a part of the display apparatus 1, for example, a portion of the display area DA, may protrude along the -z direction (or be recessed along the z direction).

Although embodiments where the display apparatus 1 is stretched in the first direction, the second direction, and/or the third direction in FIGS. 2A-2E, the present disclosure is not limited thereto. In another embodiment, the display apparatus 1 may be deformed, for example, bent or twisted, into various irregular shapes along two or more axes.

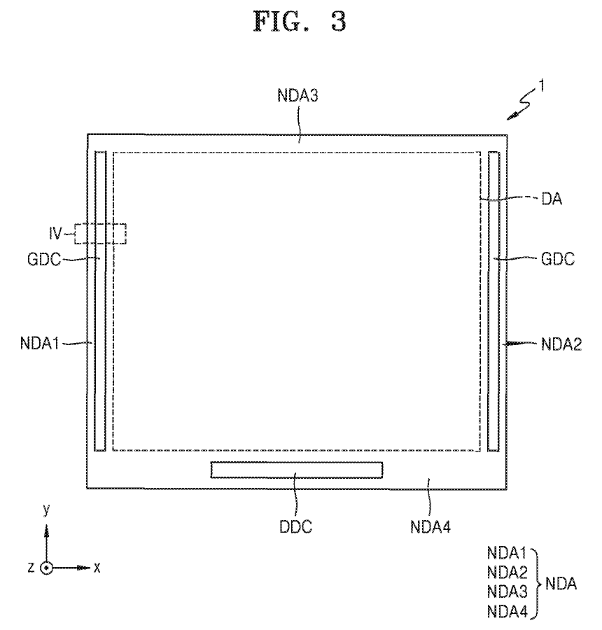

FIG. 3 is a plan view schematically illustrating a display apparatus, according to an embodiment.

Referring to FIG. 3, in an embodiment, a plurality of pixels may be arranged in the display area DA of the display apparatus 1. Each pixel may include sub-pixels emitting light of different colors. A light-emitting element (e.g., a light-emitting diode) corresponding to each sub-pixel may be disposed in the display area DA. A circuit for applying electrical signals to the light-emitting elements disposed in the display area DA and transistors electrically connected to the light-emitting elements may be located in the non-display area NDA around the display area DA. A gate driving circuit GDC may be disposed in a first non-display area NDA1 and a second non-display area NDA2 disposed on both sides of the display area DA. The gate driving circuit GDC may include drivers for applying electrical signals to gate electrodes of the transistors electrically connected to the light-emitting elements. Although an embodiment where the gate driving circuit GDC is disposed in each of the first non-display area NDA1 and the second non-display area NDA2 is illustrated in FIG. 3, the present disclosure is not limited thereto. In another embodiment, the gate driving circuit GDC may be disposed in any one of the first non-display area NDA1 and the second non-display area NDA2.

A data driving circuit DDC may be disposed in a third non-display area NDA3 and/or a fourth non-display area NDA4 connecting the first non-display area NDA1 to the second non-display area NDA2. In an embodiment, as shown in FIG. 3, the data driving circuit DDC is disposed in the fourth non-display area NDA4. In another embodiment, the data driving circuit DDC may be disposed in each of the third non-display area NDA3 and the fourth non-display area NDA4.

Although an embodiment where the data driving circuit DDC is disposed in the fourth non-display area NDA4 of the display apparatus 1 is illustrated in FIG. 3, the present disclosure is not limited thereto. In another embodiment, the display apparatus 1 may further include a flexible circuit board (not shown) electrically connected through a terminal unit (not shown) disposed in the fourth non-display area NDA4, and the data driving circuit DDC may be disposed on the flexible circuit board.

In some embodiments, an elongation of the non-display area NDA may be equal to or less than an elongation of the display area DA. In an embodiment, an elongation of the non-display area NDA may be different for each area. In an embodiment, for example, the first non-display area NDA1, the second non-display area NDA2, and the third non-display area NDA3 may have substantially a same elongation, but an elongation of the fourth non-display area NDA4 may be less than that of each of the first non-display area NDA1, the second non-display area NDA2, and the third non-display area NDA3. The term ‘elongation’ used herein refers to a value indicating a change (ΔL/L) in a length of the display apparatus 1 without physical damage to the display apparatus 1 when an external force is applied to the display apparatus 1. Here, ΔL denotes the amount of change in a length of the display apparatus 1, and L denotes an initial length of the display apparatus 1.

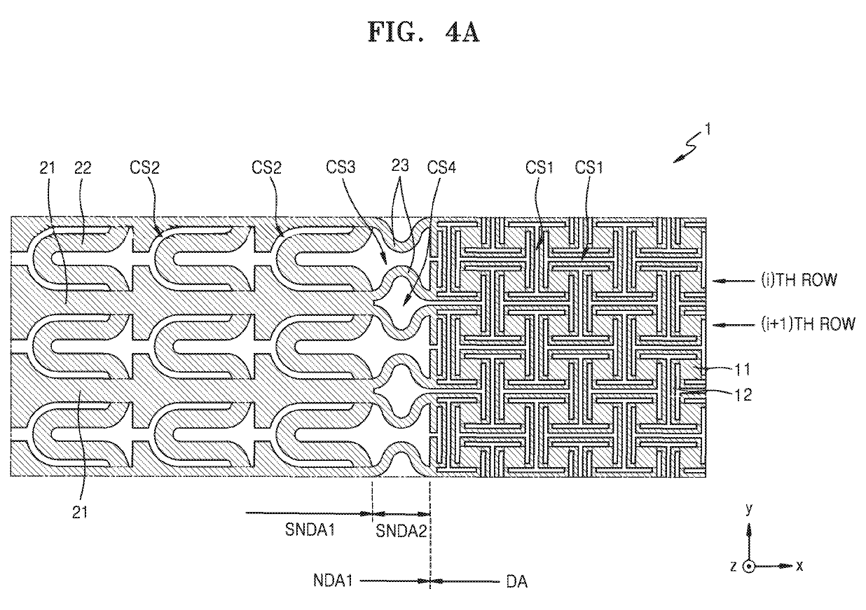

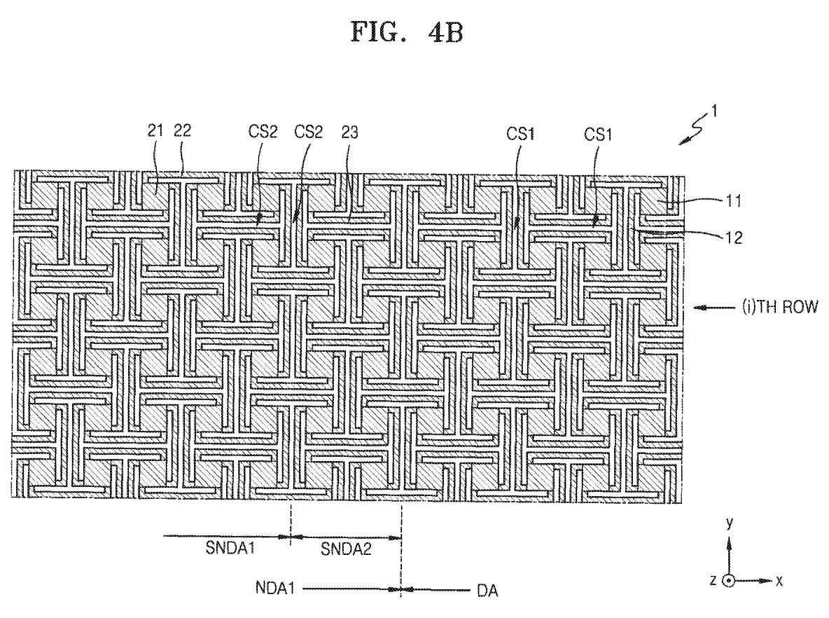

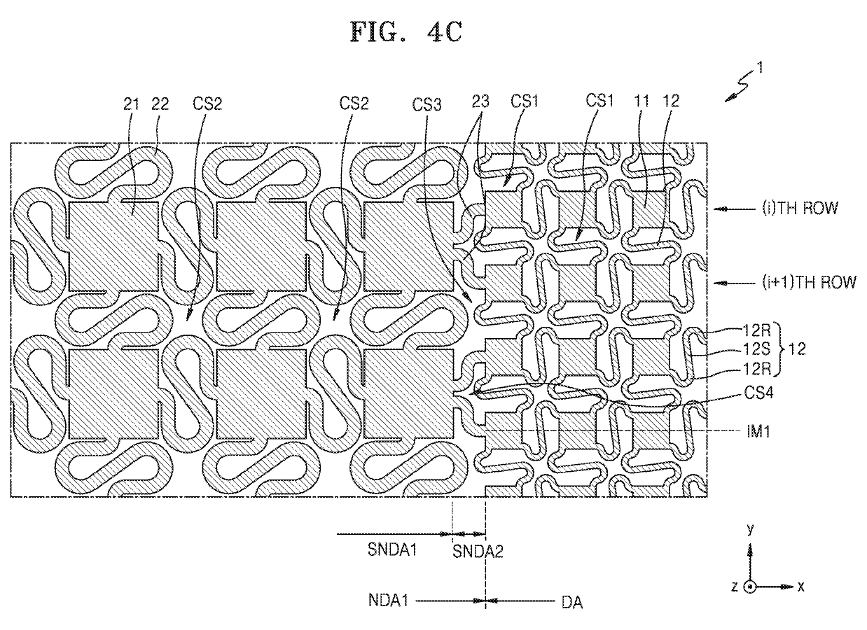

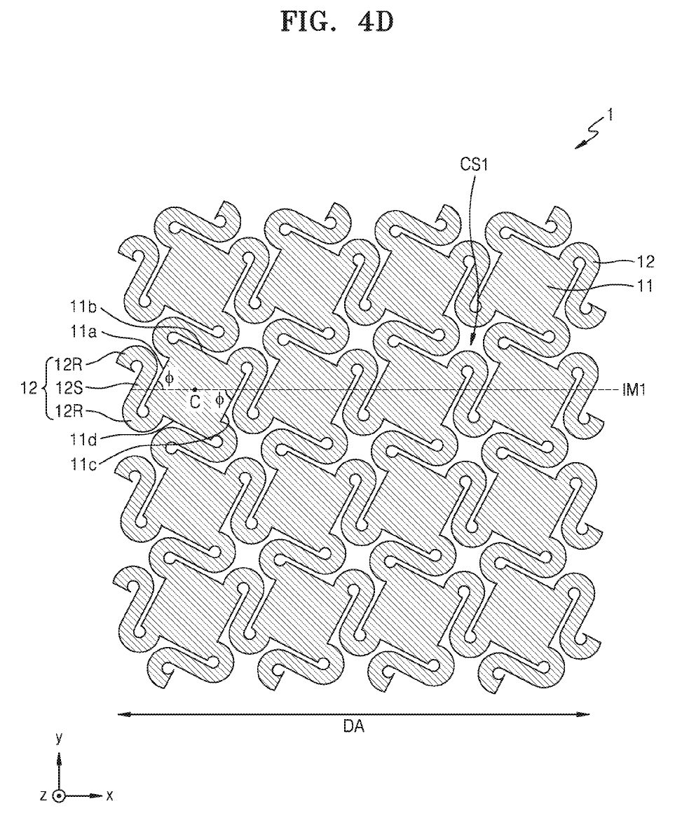

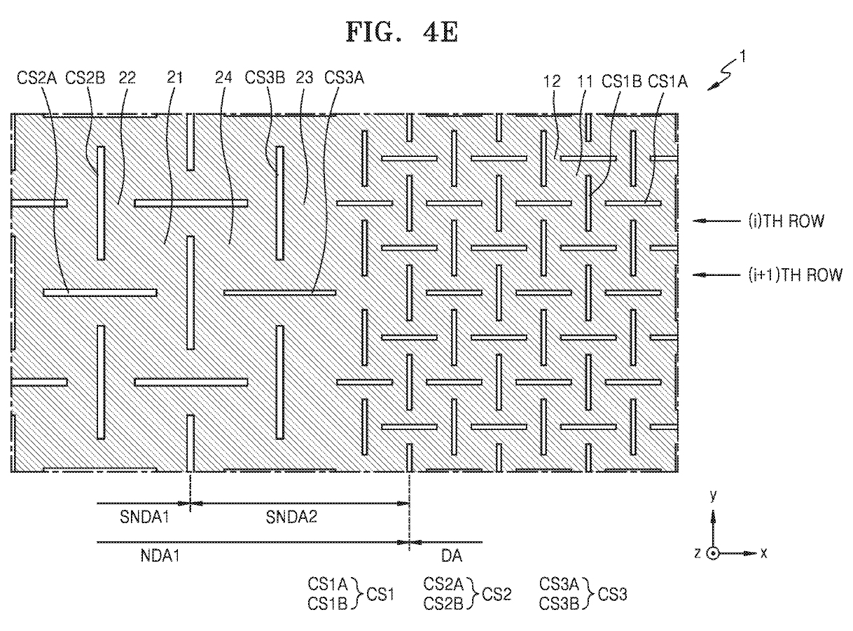

FIG. 4A is an enlarged plan view illustrating a portion IV of the display apparatus of FIG. 3, according to an embodiment.

Referring to FIG. 4A, in an embodiment, the display apparatus 1 may include first island portions 11 spaced apart from each other in the first direction (e.g., the +x direction or the -x direction) and the second direction (e.g., the +y direction or the -y direction) and first bridge portions 12 connecting adjacent first island portions 11 in the display area DA to each other.

Each first island portion 11 may be connected to a plurality of first bridge portions 12. In an embodiment, for example, each first island portion 11 may be connected to four first bridge portions 12. Two first bridge portions 12 may be disposed on both sides of the first island portion 11 along the first direction (e.g., the +x direction or the -x direction), and the remaining two first bridge portions 12 may be disposed on both sides of the first island portion 11 along the second direction (e.g., the +y direction or the -y direction). In an embodiment, the four first bridge portions 12 may be respectively connected to four sides of the first island portion 11. Each of the four first bridge portions 12 may be adjacent to each of corners of the first island portion 11.

The first bridge portions 12 may be spaced apart from each other by a first opening CS1 located between the first bridge portions 12. In an embodiment, the first opening CS1 having a substantially H shape and the first opening CS1 having a substantially I shape obtained by rotating the H shape by 90 degrees may be alternately and repeatedly arranged along the first direction (e.g., the +x direction or the -x direction) and the second direction (e.g., the +y direction or the -y direction). Both ends of each first bridge portion 12 may be respectively connected to adjacent first island portions 11, and one side of each first bridge portion 12 may be spaced apart from one side of the adjacent first island portion 11 and/or one side of another first bridge portion 12 by the first opening CS1.

The display apparatus 1 may include second island portions 21 spaced apart from each other and second bridge portions 22 connecting adjacent second island portions 21 in the non-display area, for example, the first non-display area NDA1.

Each second island portion 21 may extend along the first direction (e.g., the +x direction or the -x direction). The second island portions 21 may be spaced apart from each other along the second direction (e.g., +y direction or -y direction) intersecting the first direction (e.g., +x direction or -x direction). Each second island portion 21 may include drivers of the gate driving circuit GDC (see FIG. 3) described with reference to FIG. 3.

The second bridge portion 22 may have a serpentine shape. A length of the second bridge portion 22 may be greater than a shortest distance between the second island portions 21 adjacent to each other along the second direction (e.g., the +y direction or the -y direction). In an embodiment, the second bridge portion 22 may have a substantially omega (Ω) shape that is convex toward the first direction (e.g., the +x direction or the -x direction). The second bridge portions 22 may be disposed between adjacent second island portions 21, but may be spaced apart from each other.

The second bridge portions 22 between adjacent second island portions 21 may be spaced apart from each other by a second opening CS2. Between adjacent second island portions 21, the second openings CS2 and the second bridge portions 22 may be alternately arranged along the first direction (e.g., the +x direction or the -x direction). The second openings CS2 may have a same shape as each other. Both opposing ends of each second bridge portion 22 may be connected to adjacent second island portions 21, and one side of each second bridge portion 22 may be spaced apart from one side of the adjacent second island portion 21 and/or one side of another second bridge portion 22 by the second opening CS2.

Any one second island portion 21 disposed in the first non-display area NDA1 may correspond to the first island portions 11 of a plurality of rows arranged in the display area DA. In an embodiment, for example, any one second island portion 21 disposed in the first non-display area NDA1 may correspond to the first island portions 11 arranged in an (i)^{th} row and the first island portions 11 arranged in an (i+1)^{th} row in the display area DA (where i is a positive number greater than 0). Although an embodiment where one second island portion 21 corresponds to the first island portions 11 arranged in two rows is shown in FIG. 4A, the present disclosure is not limited thereto. In another embodiment, any one second island portion 21 disposed in the first non-display area NDA1 may correspond to the first island portions 11 arranged in n rows in the display area DA (where n is a positive number of 3 or more).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 for connecting the display area DA and the first sub-non-display area SNDA1 to each other may be disposed in the second sub-non-display area SNDA2. One end of the third bridge portion 23 may be connected to the second island portion 21 and/or the second bridge portion 22, and an opposing end of the third bridge portion 23 may be connected to the first island portion 11 and/or the first bridge portion 12.

The third bridge portion 23 may have a serpentine shape. In an embodiment, a shape of the third bridge portion 23 may be different from a shape of each of the first bridge portion 12 and the second bridge portion 22. In an embodiment, as shown in FIG. 4A, the third bridge portion 23 may have a substantially omega (Ω) shape that is convex toward the second direction (e.g., the +y direction or the -y direction). Adjacent third bridge portions 23 arranged along the second direction (e.g., the +y direction or the -y direction) may have a symmetrical structure in which one of the adjacent third bridge portions 23 is convex in the +y direction and the other is convex in the -y direction. A third opening CS3 and a fourth opening CS4 having different shapes may be repeatedly arranged between the third bridge portions 23. A width of the third bridge portion 23 may be different from a width of the first bridge portion 12 and a width of the second bridge portion 22. In an embodiment, a width of the third bridge portion 23 may be greater than a width of the first bridge portion 12 and may be less than a width of the second bridge portion 22.

FIG. 4A illustrates an embodiment where the second island portion 21 and the second bridge portion 22 of the non-display area, for example, the first non-display area NDA1, have different shapes from the first island portion 11 and the first bridge portion 12 of the display area DA. In another embodiment of the present disclosure, the second island portion 21 and the second bridge portion 22 of the non-display area may have the same shape as the first island portion 11 and the first bridge portion 12 of the display area DA.

FIG. 4B is an enlarged plan view illustrating the portion IV of the display apparatus of FIG. 3, according to an embodiment.

Referring to FIG. 4B, in an embodiment, the display apparatus 1 includes the first island portions 11 spaced apart from each other and the first bridge portions 12 spaced apart from each other by the first opening CS1 and connecting adjacent first island portions 11 in the display area DA. A structure of the display area DA of FIG. 4B may be the same as a structure of the display area DA described with reference to FIG. 4A.

The display apparatus 1 may include the second island portions 21 and the second bridge portions 22 in the non-display area, for example, the first non-display area NDA1. In an embodiment, the second island portions 21 and the second bridge portions 22 may have substantially the same shape as the first island portions 11 and the first bridge portions 12.

The second island portions 21 may be spaced apart from each other in the first direction (e.g., the +x direction or the -x direction) and the second direction (e.g., the +y direction or the -y direction) in the non-display area, for example, the first non-display area NDA1. Each of the second bridge portions 22 may connect adjacent second island portions 21 to each other. The second bridge portions 22 may be spaced apart from each other by the second opening CS2 located between the second bridge portions 22.

The second opening CS2 may have substantially the same shape as the first opening CS1. In an embodiment, for example, the second opening CS2 having a substantially H shape and the second opening CS2 having a substantially I shape may be alternately and repeatedly arranged in the non-display area, for example, the first non-display area NDA1. Both opposing ends of each second bridge portion 22 may be respectively connected to adjacent second island portions 21, and one side of each second bridge portion 22 may be spaced apart from one side of the adjacent second island portion 21 and/or one side of another second bridge portion 22 by the second opening CS2.

Each second island portion 21 may be connected to four second bridge portions 22. Each second island portion 21 may include drivers of the gate driving circuit GDC (see FIG. 3) described with reference to FIG. 3.

The second island portions 21 of any one row disposed in the first non-display area NDA1 may correspond to the first island portions 11 of any one row arranged in the display area DA. In an embodiment, for example, the second island portions 21 arranged in an (i)^{th} row along the first direction (e.g., the +x direction or the -x direction) in the first non-display area NDA1 may correspond to the first island portions 11 arranged in the same row, for example, an (i)^{th} row, in the display area DA (where i is a positive number greater than 0).

The display apparatus 1 may include the third bridge portions 23 disposed in the second sub-non-display area SNDA2 for connecting the display area DA and the first sub-non-display area SNDA1 to each other. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. In an embodiment, for example, a width of the third bridge portion 23 may be the same as a width of the first bridge portion 12 and a width of the second bridge portion 22.

FIG. 4C is an enlarged plan view illustrating the portion IV of the display apparatus of FIG. 3, according to an embodiment.

Referring to FIG. 4C, in an embodiment, the display apparatus 1 may include the first island portions 11 spaced apart from each other in the first direction (e.g., the +x direction or the -x direction) and the second direction (e.g., the +y direction or the -y direction) and the first bridge portions 12 connecting adjacent first island portions 11 in the display area DA.

The first bridge portions 12 may be spaced apart from each other by the first opening CS1 located between the first bridge portions 12. The first bridge portion 12 may have a serpentine shape. In an embodiment, for example, as shown in FIG. 4C, the first bridge portion 12 may have a substantially ‘letter S’ shape by including two round portions 12R and a straight portion 12S between the two round portions 12R.

Each first island portion 11 may be connected to a plurality of first bridge portions 12. In an embodiment, for example, each first island portion 11 may be connected to four first bridge portions 12. Two first bridge portions 12 may be disposed on both sides of the first island portion 11 along the first direction (e.g., the +x direction or the -x direction), and the remaining two first bridge portions 12 may be disposed on both sides of the first island portion 11 along the second direction (e.g., the +y direction or the -y direction). The four first bridge portions 12 may be respectively connected to four sides of the first island portion 11. Each of the four first bridge portions 12 may be adjacent to each of corners of the first island portion 11.

The display apparatus 1 may include the second island portions 21 spaced apart from each other in the first direction (e.g., the +x direction or the -x direction) and the second direction (e.g., the +y direction or the -y direction) and the second bridge portions 22 connecting adjacent second island portions 21 in the non-display area, for example, the first non-display area NDA1.

The second bridge portions 22 may be spaced apart from each other by the second opening CS2 located between the second bridge portions 22. The second bridge portion 22 may have a serpentine shape. In an embodiment, for example, as shown in FIG. 4C, the second bridge portion 22 may have a substantially ‘letter S’ shape. A size and/or a width of the second bridge portion 22 may be different from a size and/or a width of the first bridge portion 12. In an embodiment, for example, a size and/or a width of the second bridge portion 22 may be greater than a size and/or a width of the first bridge portion 12. A radius of curvature of a rounded portion of the second bridge portion 22 may be different from a radius of curvature of a rounded portion of the first bridge portion 12. In an embodiment, for example, a radius of curvature of a rounded portion of the second bridge portion 22 may be greater than a radius of curvature of a rounded portion of the first bridge portion 12.

Each second island portion 21 may be connected to a plurality of second bridge portions 22. Each second island portion 21 may be connected to four second bridge portions 22. Two second bridge portions 22 may be disposed on both sides of the second island portion 21 along the first direction (e.g., the +x direction or the -x direction), and the remaining two second bridge portions 22 may be disposed on both sides of the second island portion 21 along the second direction (e.g., the +y direction or the -y direction). In an embodiment, the four second bridge portions 22 may be respectively connected to four sides of the second island portion 21. Each second bridge portion 22 may be connected to a central portion of each side of the second island portion 21.

The second island portions 21 of any one row disposed in the first non-display area NDA1 may correspond to the first island portions 11 of a plurality of rows arranged in the display area DA. In an embodiment, for example, the second island portions 21 of any one row disposed in the first non-display area NDA1 may correspond to the first island portions 11 arranged in an (i)^{th} row and the first island portions 11 arranged in an (i+1)^{th} row of the display area DA (where i is a positive number greater than 0). In another embodiment, the second island portions 21 of any one row may correspond to the first island portions 11 arranged in n rows (where n is a positive number of 3 or more).

The non-display area, for example, the first non-display area NDA1, may include the first sub-non-display area SNDA1 in which the second island portions 21 and the second bridge portions 22 are disposed, and the second sub-non-display area SNDA2 between the first sub-non-display area SNDA1 and the display area DA. Third bridge portions 23 for connecting the display area DA and the first sub-non-display area SNDA1 to each other may be disposed in the second sub-non-display area SNDA2. One end of the third bridge portion 23 may be connected to the second island portion 21, and an opposing end of the third bridge portion 23 may be connected to the first island portion 11. In an embodiment, for example, one end of the third bridge portion 23 may be connected to a central portion of one side of the second island portion 21, and an opposing end of the third bridge portion 23 may be connected to a central portion of one side of the first island portion 11.

The third bridge portion 23 may have a serpentine shape. In an embodiment, a shape of the third bridge portion 23 may be different from a shape of each of the first bridge portion 12 and the second bridge portion 22. A width of the third bridge portion 23 may be different from a width of the first bridge portion 12 and a width of the second bridge portion 22. A width of the third bridge portion 23 may be greater than a width of the first bridge portion 12 and may be less than a width of the second bridge portion 22. The third opening CS3 and the fourth opening CS4 having different shapes may be alternately disposed between the third bridge portions 23 in the second direction (e.g., the +y direction or the -y direction).

FIG. 4D is an enlarged plan view illustrating a part of the display apparatus, that is, the display area DA of FIG. 3, according to an embodiment.

Referring to FIG. 4D, an embodiment of the display apparatus 1 may include the first island portions 11 spaced apart from each other in the first direction (e.g., the +x direction or the -x direction) and the second direction (e.g., the +y direction or the -y direction) and the first bridge portions 12 connecting adjacent first island portions 11 in the display area DA to each other. The first bridge portions 12 may be spaced apart from each other by the first opening CS1 located between the first bridge portions 12.

In an embodiment, at least one of sides of the first island portion 11 may be oblique to an imaginary line connecting centers C of the first island portions 11 along the first direction (e.g., the +x direction or the -x direction) and/or the second direction (e.g., the +y direction or the -y direction). In this regard, in FIG. 4D, the first island portion 11 includes first to fourth sides 11a, 11b, 11c, and 11d, and the first to fourth sides 11a, 11b, 11c, and 11d extend in a direction oblique to a first imaginary line IM1 connecting the centers C of the first island portions 11. Although the first imaginary line IM1 extends in the first direction (e.g., the +x direction or the -x direction) in FIG. 4D, the first imaginary line IM1 may extend along the second direction (e.g., the +y direction or the -y direction).

In an embodiment, the first side 11a and the third side 11c parallel to each other may intersect the first imaginary line IM1. A smaller angle (hereinafter, referred to as a minor angle ϕ) between the first side 11a and the first imaginary line IM1 may be greater than about 0° and less than about 90°. A minor angle ϕ between the third side 11c and the first imaginary line IM1 may be greater than 0° and less than 90°.

Each first island portion 11 may be connected to a plurality of first bridge portions 12. In an embodiment, for example, each first island portion 11 may be connected to four first bridge portions 12. Two first bridge portions 12 may be disposed on both sides of the first island portion 11 along the first direction (e.g., the +x direction or the -x direction), and the remaining two first bridge portions 12 may be disposed on both sides of the first island portion 11 along the second direction (e.g., the +y direction or the -y direction).

The first bridge portion 12 may have a serpentine shape. In an embodiment, for example, as shown in FIG. 4D, the first bridge portion 12 may have a substantially ‘letter S’ shape by including two round portions 12R and one straight portion 12S between the two round portions 12R.

In an embodiment, the straight portion 12S may be substantially parallel to a side of the first island portion 11 adjacent to the straight portion 12S as shown in FIG. 4D. In an embodiment, for example, the straight portion 12S of each of the first bridge portions 12 located on both sides of the first island portion 11 along the first direction (e.g., the +x direction or the -x direction) may be substantially parallel to a side (e.g., each of the first side 11a and the third side 11c) of the first island portion 11. The straight portion 12S of each of the first bridge portions 12 located on both sides of the first island portion 11 along the second direction (e.g., the +y direction or the -y direction) may be substantially parallel to a side (e.g., each of the second side 11b and the fourth side 11d) of the first island portion 11.

Each of the first island portions 11 of FIG. 4D may be obtained by rotating each of the first island portions 11 of FIG. 4C by a first angle (e.g., an acute angle) with respect to the center C. Accordingly, at least one of sides of the first island portion 11 may be oblique to an imaginary line connecting the centers C of the first island portions 11 along the first direction (e.g., the +x direction or the -x direction) and/or the second direction (e.g., the +y direction or the -y direction). According to the arrangement of the first island portion 11 and/or the structure of the first bridge portion 12 described above, the area of the first opening CS1 of FIG. 4D may be less than the area of the first opening CS1 of FIG. 4C, and thus, the display apparatus 1 according to an embodiment illustrated in FIG. 4D may provide a relatively high resolution image.

Although an embodiment where the straight portion 12S of the first bridge portion 12 is substantially parallel to a side of the first island portion 11 adjacent to the straight portion 12S is shown in FIG. 4D, the present disclosure is not limited thereto. In another embodiment, the straight portion 12S of the first bridge portion 12 may be oblique to a side of the first island portion 11 adjacent to the straight portion 12S as shown in FIG. 4C.

In an embodiment, a structure of the first non-display area NDA1 (see FIG. 3) of the display apparatus not disclosed in FIG. 4D may be the same as a structure of the display area DA disclosed in FIG. 4D. In an embodiment, a structure of the first non-display area NDA1 (see FIG. 3) of the display apparatus 1 not disclosed in FIG. 4D may be substantially the same as a structure of the display area DA disclosed in FIG. 4D, and the area of the second island portion disclosed in the first non-display area NDA1 (see FIG. 3) may be greater than the area of the first island portion 11. In such an embodiment, one second island portion may correspond to a plurality of first island portions 11 arranged in adjacent rows as described with reference to FIG. 4C. In an embodiment, a structure of the first non-display area NDA1 (see FIG. 3) of the display apparatus 1 not disclosed in FIG. 4D may be substantially the same as a structure of the first non-display area NDA1 illustrated in any one of FIGS. 4A-4C. As such, a structure of the first non-display area NDA1 (see FIG. 3) may be selected in various ways within a range disclosed in the present specification.

FIG. 4E is an enlarged plan view illustrating the portion IV of the display apparatus of FIG. 3, according to an embodiment.

Referring to FIG. 4E, an embodiment of the display apparatus 1 includes the first island portions 11 spaced apart from each other and the first bridge portions 12 spaced apart from each other by the first opening CS1 and connecting adjacent first island portions 11 in the display area DA.

The first opening CS1 may have a bar shape. The first opening CS1 may include a first sub-opening CS1A extending in the first direction (e.g., the +x direction or the -x direction) and a second sub-opening CS1B extending in the second direction (e.g., the +y direction or the -y direction). Each of the first sub-opening CS1A and the second sub-opening CS1B may have a bar shape. The first sub-opening CS1A and the second sub-opening CS1B may have substantially the same width and the same length as each other. A length of each of the first sub-opening CS1A and the second sub-opening CS1B is a value measured along an extension direction, and a width of each of the first sub-opening CS1A and the second sub-opening CS1B is a value measured along a direction perpendicular to a longitudinal direction (e.g., the extension direction).

The display apparatus 1 may include the second island portions 21 and the second bridge portions 22 in the non-display area, for example, the first sub-non-display area SNDA1. The second island portions 21 may be spaced apart from each other in the first direction (e.g., the +x direction or the -x direction) and the second direction (e.g., the +y direction or the -y direction) in the first sub-non-display area SNDA1. Each of the second bridge portions 22 may connect adjacent second island portions 21. The second bridge portions 22 may be spaced apart from each other by the second opening CS2 located between the second bridge portions 22.

The second opening CS2 may have a bar shape. The second opening CS2 may include a third sub-opening CS2A extending in the first direction (e.g., the +x direction or the -x direction) and a fourth sub-opening CS2B extending in the second direction (e.g., the +y direction or the -y direction). Each of the third sub-opening CS2A and the fourth sub-opening CS2B may have a bar shape. The third sub-opening CS2A and the fourth sub-opening CS2B may have substantially the same width and the same length as each other. Each second island portion 21 may be connected to four second bridge portions 22. Each second island portion 21 may include drivers of the gate driving circuit GDC (see FIG. 3) described with reference to FIG. 3. Some (or at least one) of drivers of the gate driving circuit GDC (see FIG. 3) may also be disposed in the second sub-non-display area SNDA2. In an embodiment, for example, some (or at least one) third island portions 24 may include some drivers.

One second island portion 21 disposed in the first non-display area NDA1 may correspond to the first island portions 11 of a plurality of rows arranged in the display area DA. In an embodiment, for example, any one second island portion 21 disposed in the first non-display area NDA1 may correspond to the first island portions 11 arranged in an (i)^{th} row and the first island portions 11 arranged in an (i+1)^{th} row in the display area DA (where i is a positive number greater than 0). Although an embodiment where one second island portion 21 corresponds to the first island portions 11 arranged in two rows is shown in FIG. 4E, the present disclosure is not limited thereto. In another embodiment, any one second island portion 21 disposed in the first non-display area NDA1 may correspond to the first island portions 11 arranged in n rows in the display area DA (where n is a positive number of 3 or more).

The display apparatus 1 may include the third island portions 24 and third bridge portions 23 disposed in the second sub-non-display area SNDA2 for connecting the display area DA and the first sub-non-display area SNDA1 to each other. Adjacent third island portions 24 may be spaced apart from each other by the third opening CS3 and may be connected to each other by the third bridge portions 23.

The third opening CS3 may have a bar shape. The third opening CS3 may include a fifth sub-opening CS3A extending in the first direction (e.g., the +x direction or the -x direction) and a sixth sub-opening CS3B extending in the second direction (e.g., the +y direction or the -y direction). Each of the fifth sub-opening CS3A and the sixth sub-opening CS3B may have a bar shape. The fifth sub-opening CS3A and the sixth sub-opening CS3B may have different widths and/or lengths from each other.

In an embodiment, a length of the fifth sub-opening CS3A of the third opening CS3 in the first direction (e.g., the +x direction or the -x direction) may be equal to or greater than a length of the sixth sub-opening CS3B of the third opening CS3 in the second direction (e.g., the +y direction or the -y direction). A width of the fifth sub-opening CS3A of the third opening CS3 in the second direction (e.g., the +y direction or the -y direction) may be less than a width of the sixth sub-opening CS3B of the third opening CS3 in the first direction (e.g., the +x direction or the -x direction).

In an embodiment, a length of the fifth sub-opening CS3A of the third opening CS3 in the first direction (e.g., the +x direction or the -x direction) may be the same as a length of the third sub-opening CS2A of the second opening CS2 in the first direction (e.g., the +x direction or the -x direction) and may be greater than a length of the first sub-opening CS1A of the first opening CS1 in the first direction (e.g., the +x direction or the -x direction). A width of the fifth sub-opening CS3A of the third opening CS3 in the second direction (e.g., the +y direction or the -y direction) may be less than a width of the third sub-opening CS2A of the second opening CS2 in the second direction (e.g., the +y direction or the -y direction) and may be the same as a width of the first sub-opening CS1A of the first opening CS1 in the second direction (e.g., the +y direction or the -y direction).

In an embodiment, a length of the sixth sub-opening CS3B of the third opening CS3 in the second direction (e.g., the +y direction or the -y direction) may be the same as a length of the fourth sub-opening CS2B of the second opening CS2 in the second direction (e.g., the +y direction or the -y direction) and may be greater than a length of the second sub-opening CS1B of the first opening CS1 in the second direction (e.g., the +y direction or the -y direction). A width of the sixth sub-opening CS3B of the third opening CS3 in the first direction (e.g., the +x direction or the -x direction may be the same as a width of the fourth sub-opening CS2B of the second opening CS2 in the first direction (e.g., the +x direction or the -x direction) and may be greater than a width of the second sub-opening CS1B of the first opening CS1 in the first direction (e.g., the +x direction or the -x direction).

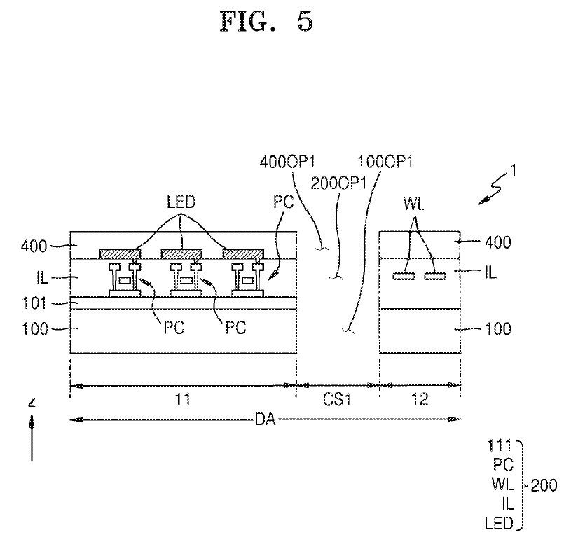

FIG. 5 is a cross-sectional view schematically illustrating a display apparatus, according to an embodiment.

Referring to FIG. 5, in an embodiment, the first island portion 11 and the first bridge portion 12 disposed in the display area DA may be spaced apart from each other with the first opening CS1 therebetween. The first island portion 11 may include light-emitting diodes LED and a circuit, for example, a pixel driving circuit unit PC, for driving light-emitting elements electrically connected thereto, and the first bridge portion 12 may include a wiring WL electrically connected to the pixel driving circuit units PC disposed in adjacent first island portions 11.

Regarding the first island portion 11, a buffer layer 101 including an inorganic insulating material may be disposed on a substrate 100, and the pixel driving circuit unit PC may be disposed on the buffer layer 101. An insulating layer IL including an inorganic insulating material and/or an organic insulating material may be disposed between the pixel driving circuit unit PC and the light-emitting diode LED. The light-emitting diode LED may be disposed on the insulating layer IL and may be electrically connected to the corresponding pixel driving circuit unit PC. The light-emitting diodes LED may emit light of different colors or light of the same color. In an embodiment, the light-emitting diodes LED may emit red light, green light, and blue light. In some embodiments, the light-emitting diodes LED may emit white light. In another embodiment, the light-emitting diodes LED may respectively emit red light, green light, blue light, and white light.

In an embodiment, three pixel driving circuit units PC are disposed in each first island portion 11 and three light-emitting diodes LED are respectively connected to the pixel driving circuit units PC as shown in FIG. 5, but the present disclosure is not limited thereto. In another embodiment, the number of pixel driving circuit units PC and light-emitting diodes LED disposed in the first island portion 11 may be one, two, or four or more.

An encapsulation layer 400 may be disposed on the light-emitting diode LED, and may protect the light-emitting diode LED from an external force and/or moisture penetration. The encapsulation layer 400 may include an inorganic encapsulation layer and/or an organic encapsulation layer. In some embodiments, the encapsulation layer 400 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 400 may include an organic material such as resin. In some embodiments, the encapsulation layer 400 may include urethane epoxy acrylate. The encapsulation layer 400 may include a photosensitive material such as a photoresist.

Regarding the first bridge portion 12, the insulating layer IL including an organic insulating material may be disposed on the substrate 100. The first bridge portion 12 that is relatively highly deformed when the display apparatus 1 is stretched may not include a layer including an inorganic insulating material that is prone to cracks, unlike the first island portion 11.

In an embodiment, the substrate 100 corresponding to the first bridge portion 12 may have a same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in a same process. In another embodiment, the substrate 100 corresponding to the first bridge portion 12 may have a stacked structure different from that of the substrate 100 corresponding to the first island portion 11. In some embodiments, the substrate 100 corresponding to the first bridge portion 12 may have a multi-layer structure including a base layer including a polymer resin and a barrier layer including an inorganic insulating material, and the substrate 100 corresponding to the first bridge portion 12 may have a structure including a polymer resin layer without a layer including an inorganic insulating material.

As described above, the wirings WL of the first bridge portion 12 may be signal lines (e.g., a gate line and a data line) for providing an electrical signal to a transistor included in the pixel driving circuit unit PC of the first island portion 11 or voltage lines (e.g., a driving voltage line and an initialization voltage line) for providing a voltage. The encapsulation layer 400 may also be disposed in the first bridge portion 12. In another embodiment, the encapsulation layer 400 may not be disposed in the first bridge portion 12.

Referring to FIGS. 4A-4E and 5, in an embodiment, the substrate 100 corresponding to the first island portion 11 and the substrate 100 corresponding to the first bridge portion 12 may be connected to each other. In other words, the plan view of FIGS. 4A-4E may be substantially the same as a plan view of the substrate 100 of FIG. 5. In other words, the substrate 100 may include an area corresponding to the first island portion 11, an area corresponding to the first bridge portion 12, and an opening 100OP1 having the same shape as the first opening CS1.

Likewise, the encapsulation layer 400 corresponding to the first island portion 11 and the encapsulation layer 400 corresponding to the first bridge portion 12 may be connected to each other. For example, the plan view of FIGS. 4A-4E may be substantially the same as a plan view of the encapsulation layer 400. In other words, the encapsulation layer 400 may include an area corresponding to the first island portion 11, an area corresponding to the first bridge portion 12, and an opening 400OP1 having the same shape as the first opening CS1.

A circuit-light-emitting element layer 200 between the substrate 100 and the encapsulation layer 400 may include the buffer layer 101, the pixel driving circuit unit PC, the wiring WL, the insulating layer IL, and the light-emitting diode LED. Like the substrate 100, the plan view of FIGS. 4A-4E may be substantially the same as a plan view of the circuit-light-emitting element layer 200. In other words, the circuit-light-emitting element layer 200 may include an opening 200OP1 having the same shape as the first opening CS1.

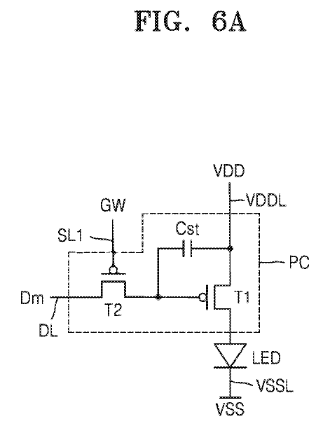

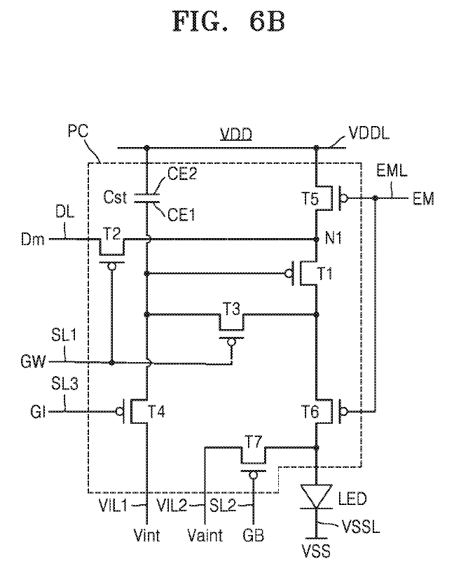

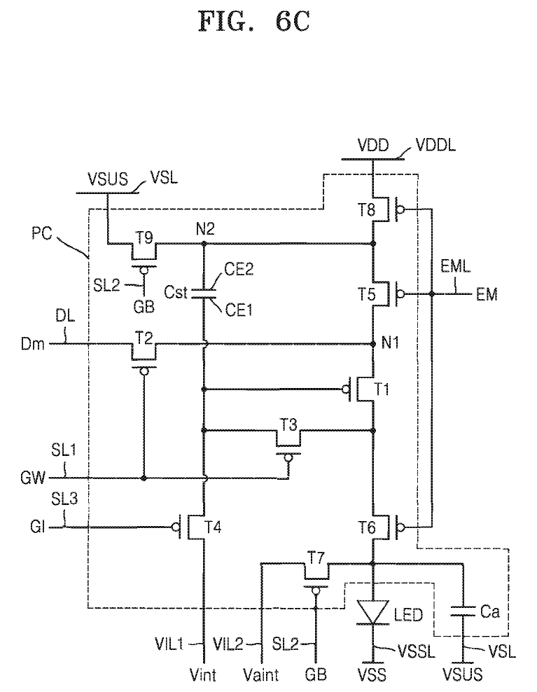

FIGS. 6A-6C are equivalent circuit diagrams illustrating a sub-pixel of a display apparatus, according to an embodiment.

Referring to FIG. 6A, in an embodiment, the light-emitting diode LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line such as a first scan line SL1 and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit a data signal Dm input from the data line DL to the first transistor T1 in response to the first scan signal GW input from the first scan line SL1.

The storage capacitor Cst may be electrically connected to the second transistor T2 and the first voltage line VDDL, and may store a voltage corresponding to a difference between a voltage received from the second transistor T2 and a first power supply voltage VDD supplied by the first voltage line VDDL.

The first transistor T1 is a driving transistor and may control driving current flowing through the light-emitting diode LED. The first transistor T1 may be connected to the first voltage line VDDL and the storage capacitor Cst. The first transistor T1 may control the driving current flowing through the light-emitting diode LED from the first voltage line VDDL in response to a value of the voltage stored in the storage capacitor Cst. The light-emitting diode LED may emit light having a certain luminance due to the driving current. A first electrode of the light-emitting diode LED may be electrically connected to the first transistor T1, and a second electrode of the light-emitting diode LED may be electrically connected to a second voltage line VSSL that supplies a second power supply voltage VSS.

Although an embodiment where the pixel driving circuit unit PC includes two transistors and one storage capacitor is in FIG. 6A, the present disclosure is not limited thereto. In another embodiment, the pixel driving circuit unit PC may include three or more transistors.

Referring to FIG. 6B, in another embodiment, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting diode LED to the pixel driving circuit unit PC.

The first transistor T1 may be electrically connected to the first voltage line VDDL via the fifth transistor T5, and may be electrically connected to the light-emitting diode LED via the sixth transistor T6. The first transistor T1 functions as a driving transistor, and receives a data signal Dm based on a switching operation of the second transistor T2 and supplies driving current to the light-emitting diode LED.

The second transistor T2 is a data write transistor and is electrically connected to the first scan line SL1 and the data line DL. The second transistor T2 is electrically connected to the first voltage line VDDL via the fifth transistor T5. The second transistor T2 is turned on in response to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting diode LED via the sixth transistor T6. The third transistor T3 may be turned on in response to the first scan signal GW received through the first scan line SL1 to diode-connect the first transistor T1.

The fourth transistor T4 is a first initialization transistor and is electrically connected to the third scan line SL3 and the first initialization voltage line VIL1. The fourth transistor T4 is turned on in response to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on in response to an emission control signal EM received through the emission control line EML to form a current path through which the driving current may flow from the first voltage line VDDL to the light-emitting diode LED.

The seventh transistor T7 is a second initialization transistor and may be electrically connected to the second scan line SL2, the second initialization voltage line VIL2, and the sixth transistor T6. The seventh transistor T7 may be turned on in response to a second scan signal GB received through the second scan line SL2 to initialize the first electrode of the light-emitting diode LED by transmitting the second initialization voltage Vaint from the second initialization voltage line VIL2 to the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

Referring to FIG. 6C, in another embodiment, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting diode LED to the pixel driving circuit unit PC. The sustain voltage line VSL may provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8, and may be electrically connected to the light-emitting diode LED via the sixth transistor T6. The first transistor T1 functions as a driving transistor, and may supply driving current to the light-emitting diode LED by receiving a data signal Dm based on a switching operation of the second transistor T2.

The second transistor T2 is electrically connected to the first scan line SL1 and the data line DL, and is electrically connected to the first voltage line VDDL via the fifth transistor T5 and the eighth transistor T8. The second transistor T2 is turned on in response to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting diode LED via the sixth transistor T6. The third transistor T3 is turned on in response to the first scan signal GW received through the first scan line SL1 to diode-connect the first transistor T1 and compensate for a threshold voltage of the first transistor T1.

The fourth transistor T4 is electrically connected to the third scan line SL3 and the first initialization voltage line VIL1, and is turned on in response to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5, the sixth transistor T6, and the eighth transistor T8 are electrically connected to the emission control line EML, and are simultaneously turned on in response to an emission control signal EM received through the emission control line EML to form a current path through which the driving current may flow from the first voltage line VDDL to the light-emitting diode LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB received through the second scan line SL2 to initialize the first electrode of the light-emitting diode LED by transmitting the second initialization voltage Vaint from the second initialization voltage line VIL2 to the first electrode of the light-emitting diode LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2 to transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on in the initialization period and the data write period, and the eighth transistor T8 may be turned on and the ninth transistor T9 may be turned off in an emission period. Because the sustain voltage VSUS is transmitted to the second node N2 in the initialization period and the data write period, the uniformity (e.g., long-range uniformity (LRU)) of luminance of the display apparatus due to a voltage drop of the first voltage line VDDL may be improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, a sustain voltage line VSSL, and the first electrode of the light-emitting diode LED. The auxiliary capacitor Ca may store and maintain a voltage corresponding to a voltage difference between the first electrode of the light-emitting diode LED and the sustain voltage line VSL while the seventh transistor T7 and the ninth transistor T9 are turned on, thereby preventing an increase in black luminance when the sixth transistor T6 is turned off.

Although FIGS. 6A-6C illustrate embodiments where transistors of the pixel driving circuit unit PC are implemented as p-channel MOSFETs (PMOSs), the present disclosure is not limited thereto. In an embodiment, at least one of transistors of the pixel driving circuit unit PC of FIG. 6A, for example, the first and second transistors T1 and T2, may be implemented as an n-channel MOSFET (NMOS). In an embodiment, at least one of transistors of the pixel driving circuit unit PC of FIG. 6B, for example, the first to seventh transistors T1, T2, T3, T4, T5, T6, and T7, may be implemented as an NMOS. In an embodiment, for example, in the pixel driving circuit unit PC of FIG. 6B, the first, second, fifth, sixth, and seventh transistors T1, T2, T5, T6, and T7 may be implemented as PMOSs, and the third and fourth transistors T3 and T4 may be implemented as NMOSs. In an embodiment, at least one of transistors of the pixel driving circuit unit PC of FIG. 6C, for example, the first to ninth transistors T1, T2, T3, T4, T5, T6, T7, T8, and T9, may be implemented as an NMOS. In an embodiment, for example, in the pixel driving circuit unit PC of FIG. 6C, the first, second, fifth, sixth, seventh, eighth, and ninth transistors T1, T2, T5, T6, T7, T8, and T9 may be implemented as PMOSs, and the third and fourth transistors T3 and T4 may be implemented as NMOSs.

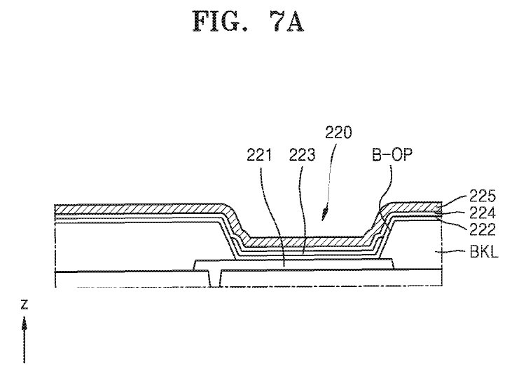

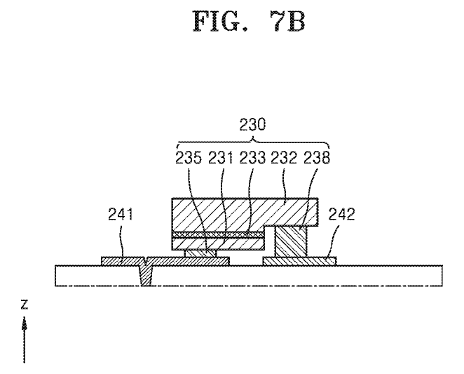

FIG. 7A is a cross-sectional view schematically illustrating a light-emitting element of a display apparatus, according to an embodiment.

Referring to FIG. 7A, a light-emitting element according to an embodiment of the present disclosure may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered by a bank layer BKL including an insulating material. The bank layer BKL may be provided with an opening B-OP overlapping a central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 221 may further include a layer including or formed of ITO, IZO, ZnO, AZO, or In₂O₃ over/under the reflective layer.

The emission layer 223 may include a high molecular weight organic material or a low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may be formed of a conductive material having a low work function. In an embodiment, for example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer including or formed of ITO, IZO, ZnO, AZO, or In₂O₃ on the (semi-)transparent layer including the above material.

FIG. 7B is a cross-sectional view schematically illustrating a light-emitting element of a display apparatus, according to an embodiment.

Referring to FIG. 7B, a light-emitting element according to an embodiment of the present disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 disposed on the same layer.

In some embodiments, the first semiconductor layer 231 may include a p-type semiconductor layer. The p-type semiconductor layer may include or be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with a p-type dopant such as Mg, Zn, Ca, Sr, or Ba.

The second semiconductor layer 232 may include, for example, an n-type semiconductor layer. The n-type semiconductor layer may include or be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with an n-type dopant such as Si, Ge, or Sn.

The intermediate layer 233 may be an area where electrons and holes recombine to change to a lower energy level and generate light having a corresponding wavelength. The intermediate layer 233 may include a semiconductor material having a composition formula of InₓAl_{y}Ga_{1-x-y}N (0≤x≤1, 0≤y≤1, 0≤x+y≤1), and may have a single or multi-quantum well (MQW) structure. In an embodiment, the intermediate layer 233 may have a quantum wire structure or a quantum dot structure.

Although an embodiment where the first semiconductor layer 231 includes a p-type semiconductor layer and the second semiconductor layer 232 includes an n-type semiconductor layer is shown in FIG. 7B, the present disclosure is not limited thereto. In another embodiment, the first semiconductor layer 231 may include an n-type semiconductor layer, and the second semiconductor layer 232 may include a p-type semiconductor layer.

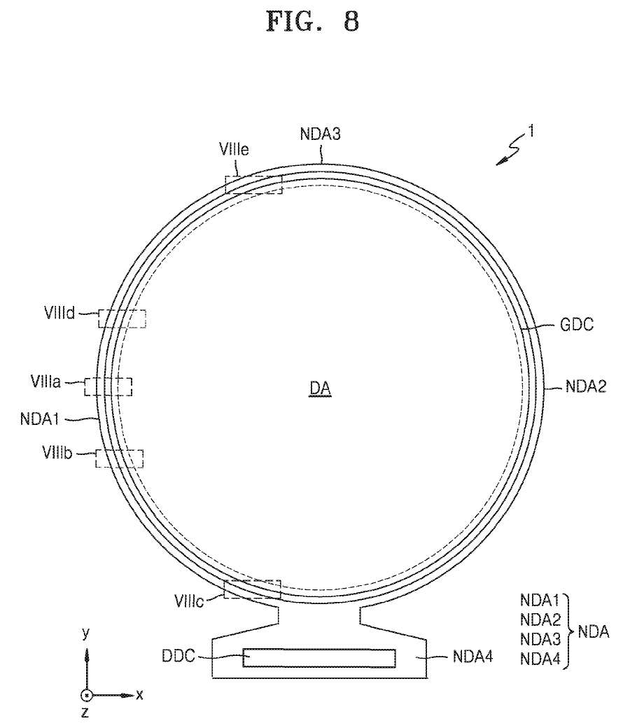

FIG. 8 is a plan view schematically illustrating a display apparatus, according to an embodiment.

Referring to FIG. 8, a plurality of pixels may be arranged in the display area DA of the display apparatus 1. Each pixel may include sub-pixels emitting light of different colors. A light-emitting element (e.g., a light-emitting diode) corresponding to each sub-pixel may be disposed in the display area DA. A circuit for applying electrical signals to the light-emitting elements disposed in the display area DA and transistors electrically connected to the light-emitting elements may be located in the non-display area NDA around the display area DA.

The display apparatus 1 and the display area DA may have a curved portion or periphery. In an embodiment, the display area DA may be provided in a substantially circular shape, and the display apparatus 1 including the display area DA and the non-display area NDA may be provided in a substantially omega (Ω) shape. The non-display area NDA may entirely surround the display area DA. The first non-display area NDA1 and the second non-display area NDA2 may be disposed on both sides of the display area DA. The third non-display area NDA3 may be disposed on one side (e.g., +y side) of the display area DA, and may connect the first non-display area NDA1 to the second non-display area NDA2. The gate driving circuit GDC is disposed across the first non-display area NDA1, the second non-display area NDA2, and the third non-display area ND3, and may at least partially (e.g., entirely) surround the display area DA. Although FIG. 8 illustrates an embodiment where the gate driving circuit GDC entirely surrounds the display area DA, the present disclosure is not limited thereto. In another embodiment, the gate driving circuit GDC may be partially open and may partially surround the display area DA. The gate driving circuit GDC may include drivers for applying electrical signals to gate electrodes of the transistors electrically connected to the light-emitting elements.

The fourth non-display area NDA4 may correspond to an area protruding from a circle corresponding to the display area DA. The data driving circuit DDC may be disposed in the fourth non-display area NDA4. Although FIG. 8 illustrates an embodiment where the fourth non-display area NDA4 includes a relatively large area in which the data driving circuit DDC is disposed and a neck area connecting the area in which the data driving circuit DDC is disposed to the display area DA, the present disclosure is not limited to the fourth non-display area NDA4 having a specific shape.

Although an embodiment where the data driving circuit DDC is disposed in the fourth non-display area NDA4 of the display apparatus 1 is shown in FIG. 8, the present disclosure is not limited thereto. In another embodiment, the display apparatus 1 may further include a flexible circuit board (not shown) electrically connected through a terminal unit (not shown) disposed in the fourth non-display area NDA4, and the data driving circuit DDC may be disposed on the flexible circuit board.

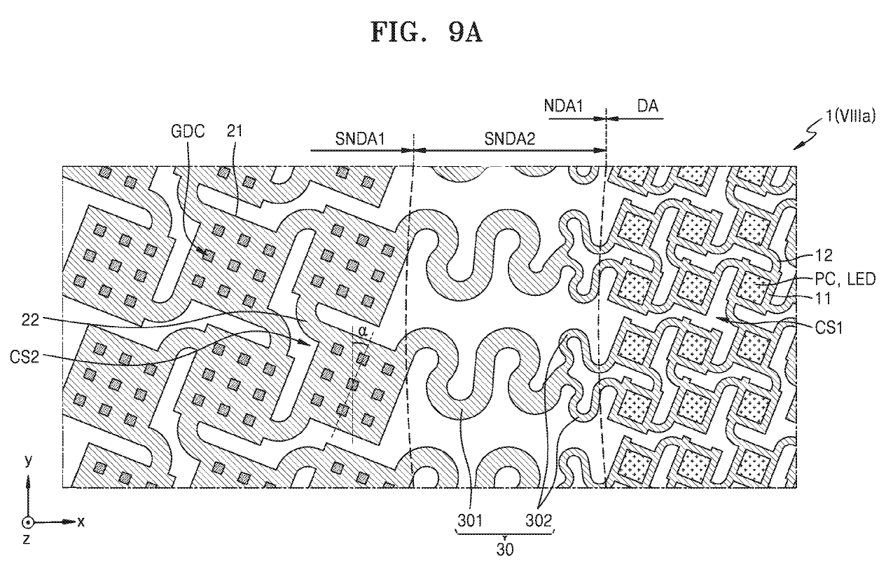

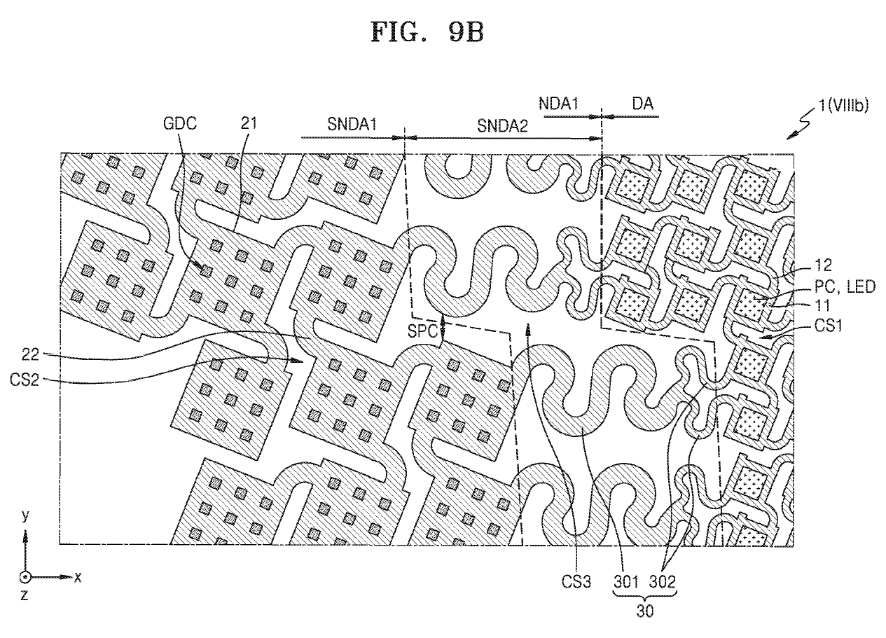

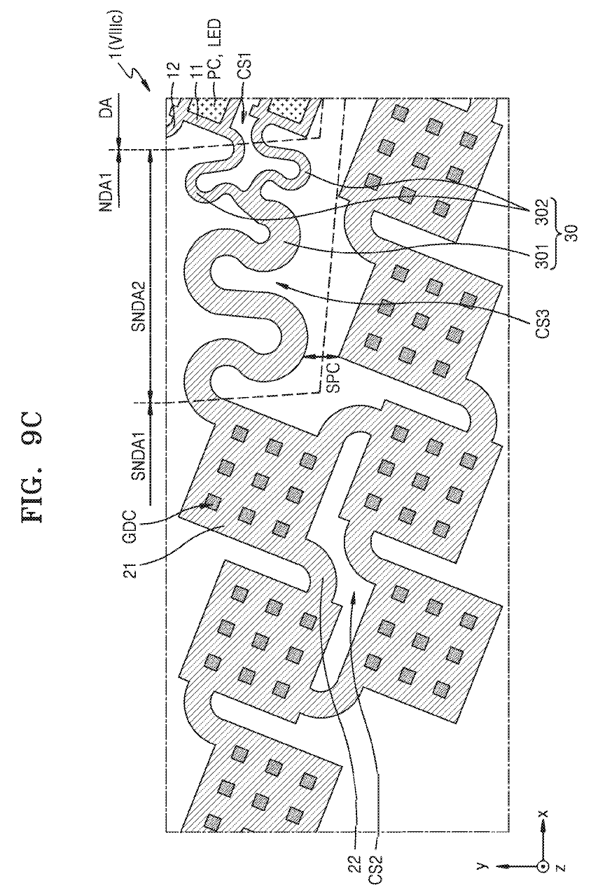

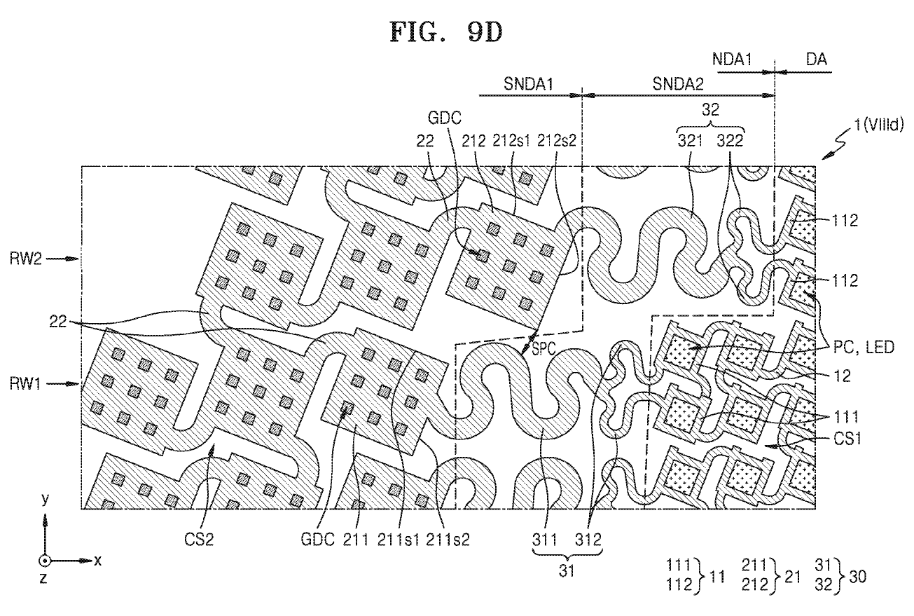

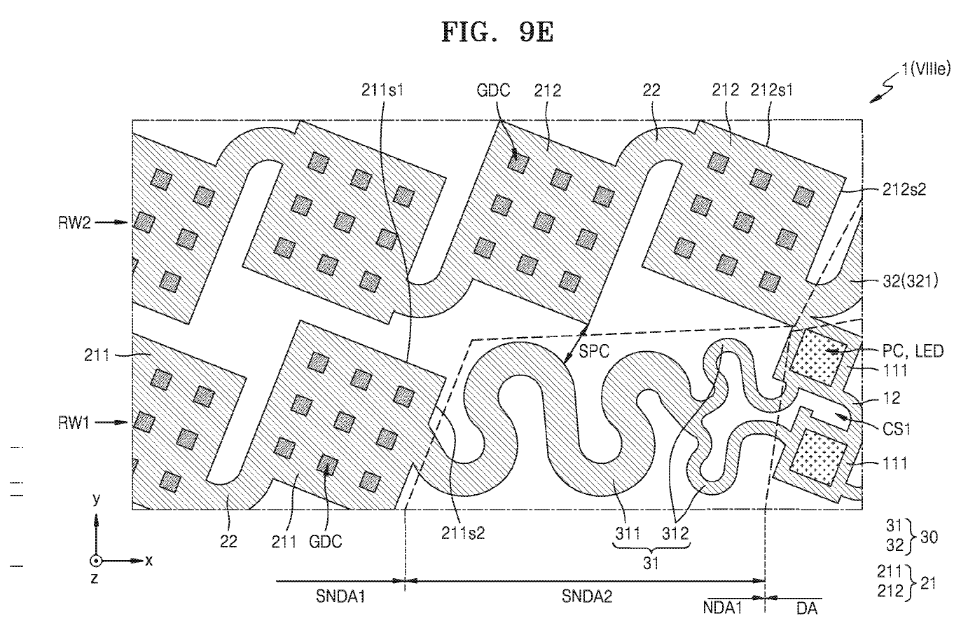

FIG. 9A is an enlarged plan view illustrating a portion VIIIa of the display apparatus of FIG. 8, according to an embodiment.

Referring to FIG. 9A, the display apparatus 1 may include the first island portions 11 spaced apart from each other in the first direction (e.g., the +x direction or the -x direction) and the second direction (e.g., the +y direction or the -y direction) and the first bridge portions 12 connecting adjacent first island portions 11 in the display area DA. The pixel driving circuit unit PC and the light-emitting diode LED may be disposed in the first island portion 11.

The first bridge portions 12 may be spaced apart from each other by the first opening CS1 located between the first bridge portions 12. The first bridge portion 12 may have a curved (e.g., serpentine) shape. In an embodiment, for example, as shown in FIG. 9A, the first bridge portion 12 may have an arc shape.

Each first island portion 11 may be connected to a plurality of first bridge portions 12.

In an embodiment, some of the first island portions 11 may be connected to three first bridge portions 12. In an embodiment, two first bridge portions 12 may be disposed on both sides of the first island portion 11 along the first direction (e.g., the +x direction or the -x direction), and the remaining one first bridge portion 12 may be disposed on one side of the first island portion 11 along the second direction (e.g., the +y direction or the -y direction). In an embodiment, one first bridge portion 12 may be disposed on one side of the first island portion 11 along the first direction (e.g., the +x direction or the -x direction), and the remaining two first bridge portions 12 may be disposed on both sides of the first island portion 11 along the second direction (e.g., the +y direction or the -y direction). The three first bridge portions 12 may be respectively connected to three of four sides of the first island portion 11. Each of the three first bridge portions 12 may be adjacent to each of corners of the first island portion 11.

In an embodiment, some of the first island portions 11 may be connected to four first bridge portions 12. In an embodiment, two first bridge portions 12 may be disposed on both sides of the first island portion 11 along the first direction (e.g., the +x direction or the -x direction), and the remaining two first bridge portions 12 may be disposed on both sides of the first island portion 11 along the second direction (e.g., the +y direction or the -y direction). The four first bridge portions 12 may be respectively connected to four sides of the first island portion 11. Each of the four first bridge portions 12 may be adjacent to each of corners of the first island portion 11.

The display apparatus 1 may include the second island portions 21 spaced apart from each other in the first direction (e.g., the +x direction or the -x direction) and the second direction (e.g., the +y direction or the -y direction) and the second bridge portions 22 connecting adjacent second island portions 21 in the non-display area, for example, the first non-display area NDA1. A driver of the gate driving circuit GDC may be disposed in the second island portion 21.

The second bridge portions 22 may be spaced apart from each other by the second opening CS2 located between the second bridge portions 22. The second bridge portion 22 may have a curved (e.g., serpentine) shape. In an embodiment, for example, as shown in FIG. 9A, the second bridge portion 22 may have an arc shape.

In an embodiment, a size and/or a width of the second bridge portion 22 may be different from a size and/or a width of the first bridge portion 12. In an embodiment, for example, a size and/or a width of the second bridge portion 22 may be greater than a size and/or a width of the first bridge portion 12. In an embodiment, a radius of curvature of a curved portion of the second bridge portion 22 may be different from a radius of curvature of a curved portion of the first bridge portion 12. In an embodiment, for example, a radius of curvature of a rounded portion of the second bridge portion 22 may be greater than a radius of curvature of a rounded portion of the first bridge portion 12. In an embodiment, a radius of curvature of a curved portion of the second bridge portion 22 may be the same as a radius of curvature of a curved portion of the first bridge portion 12.

Each second island portion 21 may be connected to a plurality of second bridge portions 22.

In an embodiment, some of the second island portions 21 may be connected to three second bridge portions 22. In an embodiment, two second bridge portions 22 may be disposed on both sides of the second island portion 21 along the first direction (e.g., the +x direction or the -x direction), and the remaining one second bridge portions 22 may be disposed on one side of the second island portion 21 along the second direction (e.g., the +y direction or the -y direction). In an embodiment, one second bridge portion 22 may be disposed on one side of the second island portion 21 along the first direction (e.g., the +x direction or the -x direction), and the remaining two second bridge portions 22 may be disposed on both sides of the second island portion 21 along the second direction (e.g., the +y direction or the -y direction). The three second bridge portions 22 may be respectively connected to three of four sides of the second island portion 21. Each of the three second bridge portions 22 may be adjacent to each of corners of the second island portion 21.

In an embodiment, some of the second island portions 21 may be connected to four second bridge portions 22. In an embodiment, two second bridge portions 22 may be disposed on both opposing sides of the second island portion 21 along the first direction (e.g., the +x direction or the -x direction), and the remaining two second bridge portions 22 may be disposed on both opposing sides of the second island portion 21 along the second direction (e.g., the +y direction or the -y direction). The four second bridge portions 22 may be respectively connected to four sides of the second island portion 21. Each of the four second bridge portions 22 may be adjacent to each of corners of the second island portion 21.

A size of the first island portion 11 and a size of the second island portion 21 may be different from each other. In an embodiment, the second island portion 21 may be larger than the first island portion 11. The second island portions 21 of any one row disposed in the first non-display area NDA1 may correspond to the first island portions 11 of a plurality of rows arranged in the display area DA. In an embodiment, the second island portions 21 of one row disposed in the first non-display area NDA1 may correspond to the first island portions 11 of two rows arranged in the display area DA. In another embodiment, the second island portions 21 of one row may correspond to the first island portions 11 arranged in n rows (where n is a positive number of 3 or greater).

The non-display area, for example, the first non-display area NDA1, may include the first sub-non-display area SNDA1 in which the second island portions 21 and the second bridge portions 22 are disposed, and the second sub-non-display area SNDA2 between the first sub-non-display area SNDA1 and the display area DA. Connecting portions 30 for connecting the display area DA and the first sub-non-display area SNDA1 to each other may be disposed in the second sub-non-display area SNDA2. One end of the connecting portion 30 may be connected to the second island portion 21, and an opposing end of the connecting portion 30 may be connected to the first island portion 11. In an embodiment, for example, one end of the connecting portion 30 may be connected to one side of the second island portion 21, and an opposing end of the connecting portion 30 may be connected to one side of the first island portion 11. The connecting portions 30 may be spaced apart from each other through the third opening CS3. The connecting portion 30 may correspond to the third bridge portion 23 described with reference to FIGS. 4A-4E in that the connecting portion 30 connects the first island portion 11 to the second island portion 21.

The connecting portion 30 may have a serpentine shape. In an embodiment, the connecting portion 30 may include a first sub-connecting portion 301 and a second sub-connecting portion 302. The first sub-connecting portion 301 may be disposed adjacent to the first sub-non-display area SNDA1 and may be connected to the second island portion 21. The second sub-connecting portion 302 may be disposed adjacent to the display area DA and may be connected to the first island portion 11. The first sub-connecting portion 301 and the second sub-connecting portion 302 may be connected to each other. In an embodiment, the first sub-connecting portion 301 and the second sub-connecting portion 302 may be integrally formed with each other as a single unitary indivisible part. In an embodiment, one first sub-connecting portion 301 may be connected to a plurality of second sub-connecting portions 302. . In an embodiment, for example, one first sub-connecting portion 301 may be connected to two second sub-connecting portions 302. In an embodiment, one first sub-connecting portion 301 may be connected to one second island portion 21, one second sub-connecting portion 302 may be connected to one first island portion 11, and one first sub-connecting portion 301 may be connected to a plurality of second sub-connecting portions 302. Accordingly, the second island portions 21 of one row may correspond to the first island portions 11 of a plurality of rows.

The first sub-connecting portion 301 and the second sub-connecting portion 302 may have different widths from each other. In an embodiment, a width of the first sub-connecting portion 301 may be greater than a width of the second sub-connecting portion 302. In an embodiment, a width of the first sub-connecting portion 301 may be the same as a width of the second bridge portion 22. In an embodiment, a width of the second sub-connecting portion 302 may be the same as a width of the first bridge portion 12.

The first island portion 11 and the second island portion 21 may be oblique to the second direction (e.g., the +y direction or the -y direction). . In an embodiment, for example, the first island portion 11 and the second island portion 21 may be rotated (e.g., tilted) by a first angle (α) clockwise with respect to the second direction (e.g., the +y direction or the -y direction). In an embodiment, all of the first island portions 11 and all of the second island portions 21 may be rotated (e.g., tilted) by a same angle (e.g., the first angle (α)) in the same rotational direction (e.g., clockwise) with respect to the same direction (e.g., the second direction).

FIG. 9B is an enlarged plan view illustrating a portion VIIIb of the display apparatus of FIG. 8, according to an embodiment. FIG. 9C is an enlarged plan view illustrating a portion VIIIc of the display apparatus of FIG. 8, according to an embodiment.

Referring to FIGS. 8, 9B, and 9C, the display apparatus 1 and the display area DA may have a curved portion or periphery. The first island portion 11, the first bridge portion 12, the second island portion 21, the second bridge portion 22, and the connecting portion 30 may be provided as one row extending along the first direction (e.g., the +x direction or the -x direction), the row may include a plurality of rows, and the plurality rows may be arranged along the second direction (e.g., the +y direction or the -y direction). Because the first direction (e.g., the +x direction or the -x direction) and the second direction (e.g., the +y direction or the -y direction) may be linear directions, in order to correspond to the curved portion of the display apparatus 1 and the display area DA, one of rows of the first island portion 11, the first bridge portion 12, the second island portion 21, the second bridge portion 22, and the connecting portion 30 may be shifted in the first direction (e.g., the +x direction or the -x direction) compared to another row adjacent in the second direction (e.g., the +y direction or the -y direction).

Referring to FIG. 9B, when viewed along the second direction (e.g., the +y direction or the -y direction), the second island portion 21 of one row may overlap the connecting portion 30 of another row, that is, the second island portion 21 of one row may overlap the connecting portion 30 of another row in the second direction. When viewed along the second direction (e.g., the +y direction or the -y direction), the first sub-connecting portion 301 of one row may overlap the second sub-connecting portion 302 of another row, that is, the first sub-connecting portion 301 of one row may overlap the second sub-connecting portion 302 of another row in the second direction. When viewed along the second direction (e.g., the +y direction or the -y direction), the connecting portion 30 of one row may overlap the first island portion 11 of another row, that is, the connecting portion 30 of one row may overlap the first island portion 11 of another row in the second direction.

Due to the shift, there may be a space SPC between the connecting portion 30 and the second island portion 21, for example, between the first sub-connecting portion 301 and the second island portion 21, which are adjacent to each other in the second direction (e.g., the +y direction or the -y direction). In such a portion (e.g., the portion VIIIb) of the display apparatus 1, despite the tilted structure of the second island portion 21, a sufficient space SPC may be secured between the first sub-connecting portion 301 and the second island portion 21, for example, between a lower end of the first sub-connecting portion 301 and an upper end of the second island portion 21.

Referring to FIGS. 8 and 9C, it may be found that the shift of the row due to the curvature of the display apparatus 1 or the display area DA becomes more severe toward an end of the display apparatus 1 or the display area DA in the second direction (e.g., the +y direction or the -y direction). When viewed along the second direction (e.g., the +y direction or the -y direction), the connecting portion 30 may overlap a plurality of second island portions 21, that is, the connecting portion 30 may overlap a plurality of second island portions 21 in the second direction. When viewed along the second direction (e.g., the +y direction or the -y direction), the second island portion 21 may overlap the first island portion 11, that is, the second island portion 21 may overlap the first island portion 11 in the second direction. In such a portion (e.g., the portion VIIIc) of the display apparatus 1, despite the tilted structure of the second island portion 21, a sufficient space SPC may be secured between the first sub-connecting portion 301 and the second island portion 21, for example, between a lower end of the first sub-connecting portion 301 and an upper end of the second island portion 21.

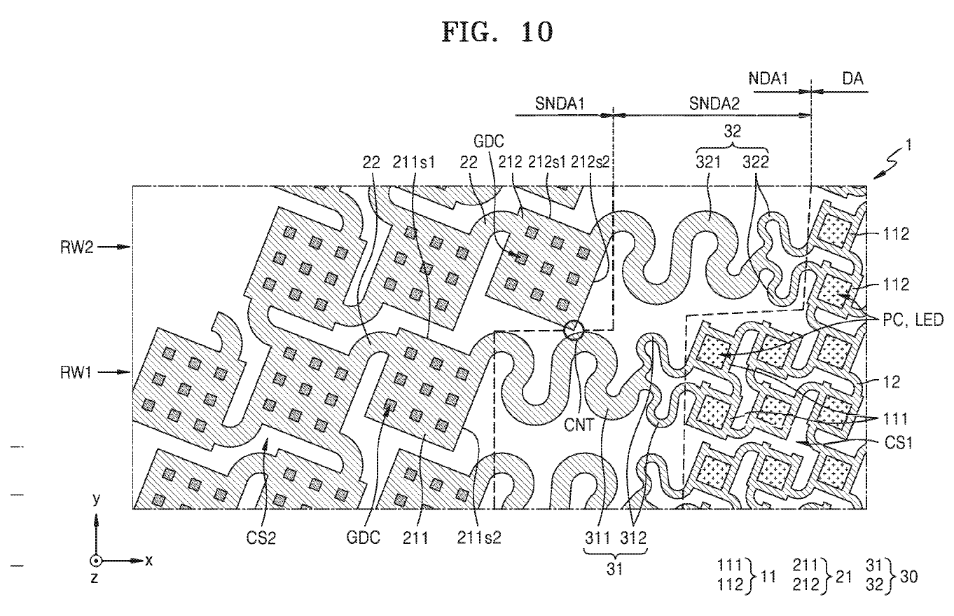

FIG. 9D is an enlarged plan view illustrating a portion VIIId of the display apparatus of FIG. 8, according to an embodiment. FIG. 9E is an enlarged plan view illustrating a portion VIIIe of the display apparatus of FIG. 8, according to an embodiment. FIG. 10 is an enlarged plan view illustrating a part of a display apparatus, as a comparative example, to which a characteristic structure of the present disclosure is not applied. FIG. 10 illustrates a portion of the display apparatus of the comparative example corresponding to the portion VIIId of FIG. 9D.

First, a problem to be solved by the present disclosure will be described with reference to FIG. 10. Referring to FIGS. 8 and 10, a shift of a row due to the curvature of the display apparatus 1 and the display area DA may occur in an upper portion (e.g., the portion VIIId and the portion VIIIe) of the display apparatus 1 as well as in a lower portion (e.g., the portion VIIIb and the portion VIIIc) of the display apparatus 1.

In the portion VIIIb and the portion VIIIc of the display apparatus 1, despite the tilted structure of the second island portion 21, a sufficient space SPC (see FIGS. 9B and 9C) may be secured between the first sub-connecting portion 301 and the second island portion 21 adjacent to each other. On the other hand, in the portion VIIId and the portion VIIIe of the display apparatus 1, because the first sub-connecting portion 301 and the second island portion 212 are not sufficiently spaced apart from each other, contact and/or short circuit (due to contact or a short distance) may occur. In FIG. 10, a contact area CNT where contact and/or short circuit occurs is marked by a solid circle.

Embodiments of the present disclosure provide a structure capable of securing a sufficient space SPC by sufficiently spacing apart the connecting portion 30 and the second island portion 21 to effectively prevent contact and/or short circuit between the connecting portion 30 and the second island portion 21 occurring in a specific area (e.g., the contact area CNT) of the display apparatus 1 as described above.

Referring to FIGS. 9D and 9E, the first island portion 11 may include a first first island portion (hereinafter, will be referred to as “1-1 island portion”) 111 and a second first island portion (hereinafter, will be referred to as “1-2 island portion”) 112. The second island portion 21 may include a first second island portion (hereinafter, will be referred to as “2-1 island portion”) 211 and a second second island portion (hereinafter, will be referred to as “2-2 island portion”) 212. The connecting portion 30 may include a first connecting portion 31 and a second connecting portion 32.

The display apparatus 1 may include a first row RW1 and a second row RW2. The first row RW1 and the second row RW2 may each extend along the first direction (e.g., the +x direction or the -x direction) and may be arranged along the second direction (e.g., the +y direction or the -y direction). In other words, the first row RW1 and the second row RW2 may be spaced apart from each other along the second direction (e.g., the +y direction or the -y direction). In an embodiment, the second row RW2 may be disposed in a +y direction relative to the first row RW1.

The first row RW1 may include the 1-1 island portion 111, the first connecting portion 31, and the 2-1 island portion 211 arranged in the first direction (e.g., the +x direction or the -x direction). The 1-1 island portion 111 may be disposed inn the display area DA. The 2-1 island portion 211 may be disposed in the non-display area, for example, the first sub-non-display area SNDA1. The first connecting portion 31 may be disposed in the non-display area, for example, the second sub-non-display area SNDA2, and may connect the 1-1 island portion 111 to the 2-1 island portion 211. One end of the first connecting portion 31 may be connected to the 1-1 island portion 111, and an opposing end of the first connecting portion 31 may be connected to the 2-1 island portion 211. In an embodiment, for example, the first connecting portion 31 may include a second first sub-connecting portion (hereinafter, will be referred to as “1-2 sub-connecting portion”) 312 connected to the 1-1 island portion 111 and a first first sub-connecting portion (hereinafter, will be referred to as “1-1 sub-connecting portion”) 311 connected to the 2-1 island portion 211. One 1-1 sub-connecting portion 311 may be connected to a plurality of 1-2 sub-connecting portions 312. Accordingly, in the first row RW1, one 2-1 island portion 211 may correspond to a plurality of 1-1 island portions 111. The first connecting portion 31, for example, the 1-1 sub-connecting portion 311 and the 1-2 sub-connecting portion 312, may have a serpentine shape.

The second row RW2 may include the 1-2 island portion 112, the second connecting portion 32, and the 2-2 island portion 212 which are arranged in the first direction (e.g., the +x direction or the -x direction). The 1-2 island portion 112 may be disposed in the display area DA. The 2-2 island portion 212 may be disposed in the non-display area, for example, the first sub-non-display area SNDA1. The second connecting portion 32 may be disposed in the non-display area, for example, the second sub-non-display area SNDA2, and may connect the 1-2 island portion 112 to the 2-2 island portion 212. One end of the second connecting portion 32 may be connected to the 1-2 island portion 112, and an opposing end of the second connecting portion 32 may be connected to the 2-2 island portion 212. In an embodiment, for example, the second connecting portion 32 may include a 2-2 sub-connecting portion 322 connected to the 1-2 island portion 112 and a 2-1 sub-connecting portion 321 connected to the 2-2 island portion 212. One 2-1 sub-connecting portion 321 may be connected to a plurality of 2-2 sub-connecting portions 322. Accordingly, in the second row RW2, one 2-2 island portion 212 may correspond to a plurality of 1-2 island portions 112. The second connecting portion 32, for example, the 2-1 sub-connecting portion 321 and the 2-2 sub-connecting portion 322, may have a serpentine shape.

The 1-1 island portion 111 and the 1-2 island portion 112 may have a same shape and size as each other. The 2-1 island portion 211 and the 2-2 island portion 212 may have a same shape and size as each other. In an embodiment, the 1-1 island portion 111, the 1-2 island portion 112, the 2-1 island portion 211, and the 2-2 island portion 212 may be rotated (e.g., tilted) by a same angle (e.g., the first angle (α)) (see FIG. 9A) with respect to the second direction (e.g., the +y direction or the -y direction), using the third direction (e.g., the +z direction or the -z direction) as a rotational axis.

The display apparatus 1 may include a plurality of 1-1 island portions 111 and a plurality of 1-2 island portions 112. The first bridge portion 12 may connect between the plurality of 1-1 island portions 111, between the plurality of 1-2 island portions 112, and between the 1-1 island portion 111 and the 1-2 island portion 112 adjacent to each other. The display apparatus 1 may include a plurality of 2-1 island portions 211 and a plurality of 2-2 island portions 212. The second bridge portion 22 may be connected between the plurality of 2-1 island portions 211, between the plurality of 2-2 island portions 212, and between the 2-1 island portion 211 and the 2-2 island portion 212 adjacent to each other.

When viewed along the second direction (e.g., the +y direction or the -y direction), the first connecting portion 31 (e.g., the 1-1 sub-connecting portion 311) and the 2-2 island portion 212 may overlap each other. In an embodiment where a shape of the first connecting portion 31 is as shown in FIG. 10, the contact area CNT may be formed between the first connecting portion 31, for example, the 1-1 sub-connecting portion 311, and the 2-2 island portion 212. In an embodiment, the first connecting portion 31 and the second connecting portion 32 may have a same shape as each other but different orientations In an embodiment, the first connecting portion 31 may have a shape inverted from a shape of the second connecting portion 32 about the first direction (e.g., the +x direction or the -x direction), that is, with respect to an axis of symmetry in the first direction. In other words, the first connecting portion 31 and the second connecting portion 32 may be symmetrical to each other about the first direction (e.g., the +x direction or the -x direction), that is, with respect to an axis of symmetry in the first direction. Accordingly, despite the serpentine shape of the first connecting portion 31 and the tilted orientation of the 2-2 island portion 212, a sufficient space SPC may be secured between the 1-1 sub-connecting portion 311 and the 2-2 island portion 212.

The 2-1 island portion 211 may have a first surface 211s1 and a second surface 211s2 extending in different directions to intersect and meet each other at one corner. The 1-1 sub-connecting portion 311 may be connected to the second surface 211s2 of the 2-1 island portion 211. The 2-2 island portion 212 may have a first surface 212s1 and a second surface 212s2 extending in different directions to intersect and meet at one corner. The 2-1 sub-connecting portion 321 may be connected to the first surface 212s1 of the 2-2 island portion 212. The first surface 211s1 of the 2-1 island portion 211 and the first surface 212s1 of the 2-2 island portion 212 may be parallel to each other. The second surface 211s2 of the 2-1 island portion 211 and the second surface 212s2 of the 2-2 island portion 212 may be parallel to each other. The connection of the 1-1 sub-connecting portion 311 and the 2-1 sub-connecting portion to surfaces extending in different directions may result from different orientations of the first connecting portion 31 and the second connecting portion 32.

Referring to FIGS. 8, 9A-9E, and 10 together, the inverted structure of connecting portions of adjacent rows as described above, for example, the inverted structure of the first connecting portion 31 of the first row RW1 and the second connecting portion 32 of the second row RW2, may be applied to an area (see FIG. 10) where rows are shifted due to the curvature of the display apparatus 1 and the display area DA and contact occurs between the second island portion 21 and the connecting portion 30 due to the shift. In an embodiment, for example, the above-described shift and contact may occur in an upper left area (e.g., -x and +y side) of the display apparatus 1, the above-described inverted structure may be applied to effectively prevent a contact therebetween, and such an embodiment is illustrated in FIGS. 9D and 9E. Although not shown in the drawings, the above-described shift and contact may also occur in a lower right area (e.g., +x and -y side) of the display apparatus 1, and the above-described inverted structure may also be applied to the lower right area.

In a lower left area (e.g., -x and -y side) of the display apparatus 1, despite the above-described shift, a sufficient space SPC may be secured between the second island portion 21 and the connecting portion 30 (see FIGS. 9B and 9C). Likewise, even in an upper right area (e.g., +x and +y side) of the display apparatus 1, despite the above-described shift, a sufficient space may be secured between the second island portion 21 and the connecting portion 30. Accordingly, the above-described inverted structure may or may not be applied to the area.

The reason why, despite the overall occurrence of row shifts caused by the curvature of the display apparatus 1 and the display area DA, contact between the second island portion 21 and the first connecting portion 31 occurs only in some areas and the inverted structure for preventing such contact is applied may be in a tilting direction of the first island portion 11 and the second island portion 21. In an embodiment, for example, because the first island portion 11 and the second island portion 21 are rotated (e.g., tilted) clockwise with respect to the second direction (e.g., the +y direction or the -y direction), using the third direction (e.g., the +z direction or the -z direction) as a rotational axis, contact may occur due to the above-described shift in the upper left area (e.g., +x and +y side) of the display apparatus 1 and/or the lower right area (e.g., +x and -y side) of the display apparatus 1.

Accordingly, in a case where the first island portion 11 and the second island portion 21 are rotated (e.g., tilted) in a different direction, for example, counterclockwise, contact due to the above-described shift may occur in the lower left area (e.g., -x and -y side) and/or the upper right area (e.g., +x and +y side) of the display apparatus 1. In this case, the inverted structure of the first connecting portion 31 and the second connecting portion 32 may be applied to the lower left area (e.g., -x and -y side) and/or the upper right area (e.g., +x and +y side) of the display apparatus 1.

In other words, an area of the display apparatus 1 to which a structure in which the first connecting portion 31 and the second connecting portion 32 have an inverted shape is applied is not fixed. The core idea of the present disclosure is to, when rows including components of the display apparatus 1 (e.g., the first island portion 11 and the second island portion 21) are shifted in the first direction (e.g., the +x direction or the -x direction) due to the curvature of the display apparatus 1 and/or the display area DA and contact occurs (e.g., due to the shift and tilting of components) between components (e.g., contact between the connecting portion 30 and the second island portion 21) between adjacent rows in the second direction (e.g., the +y direction or the -y direction) intersecting the first direction (e.g., the +x direction or the -x direction), the contact therebetween may be effectively prevented by changing (e.g., inverting) orientations of some (e.g., the connecting portion 30) of the components. The core idea of the present disclosure is not limited to a specific spatial area, but may be applied to any area where the above-described shift and contact occur. Because the connecting portion 30 may have a serpentine structure, the inverted structure as a structure for preventing contact due to the above-described shift may provide a much simpler solution than implementing the connecting portion 30 having a new shape.

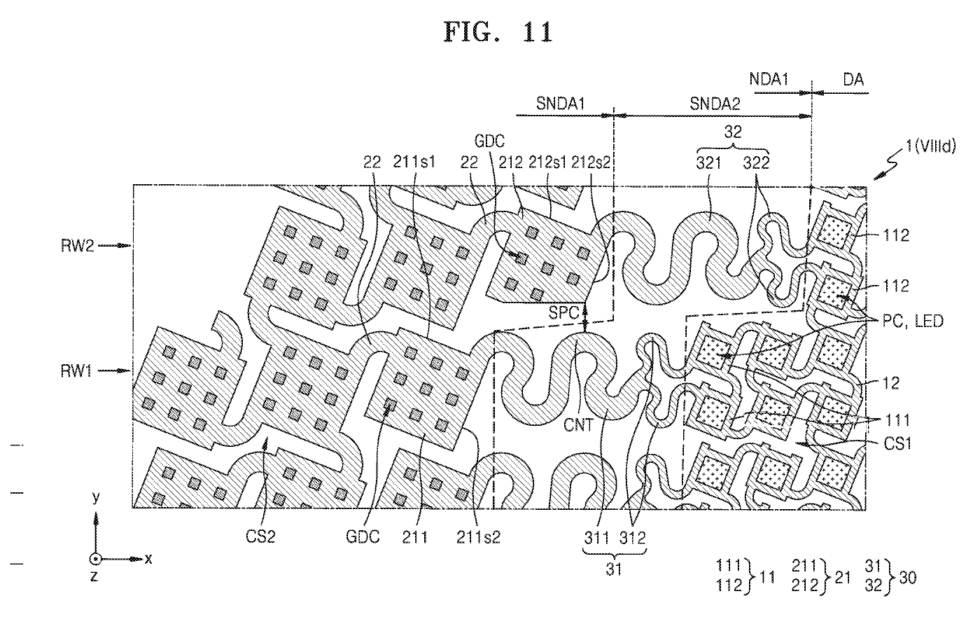

FIG. 11 is an enlarged plan view illustrating the portion VIIId of the display apparatus of FIG. 8, according to an embodiment.

Referring to FIG. 11, another solution for solving the above-described shift and contact will be described. In an embodiment, the first connecting portion 31 (e.g., the 1-1 sub-connecting portion 311) and the 2-2 island portion 212 may overlap each other in the second direction. In an embodiment, the area of the 2-2 island portion 212 may be less than the area of the 2-1 island portion 211.

In other words, the 2-2 island portion 212 may have a shape obtained by cutting a portion of the 2-1 island portion 211. Due to the shape of the 2-2 island portion 212 that is partially cut off, the space SPC may be secured between a lower end of the 2-2 island portion 212 and an upper end of the 1-1 sub-connecting portion 311. In an embodiment, the area of the 2-2 island portion 212 may be about 50% to about 90% of the area of the 2-1 island portion 211. In an embodiment, the area of the 2-2 island portion 212 may be about 80% to about 90% of the area of the 2-1 island portion 211.

In an embodiment, because the space SPC is secured due to the shape of the 2-2 island portion 212, the above-described inverted structure may not need to be applied. Accordingly, in an embodiment, the first connecting portion 31 and the second connecting portion 32 may have a same shape as each other. In an embodiment, the 1-1 sub-connecting portion 311 may be connected to the first surface 211s1 of the 2-1 island portion 211, and the 2-1 sub-connecting portion 321 may be connected to the first surface 212s1 of the 2-2 island portion 212.

In other words, embodiments provide a structure in which one portion of one of adjacent components, for example, a portion adjacent to another component, is cut off, as a structure for preventing contact due to the above-described shift. In an embodiment, for example, a part of the 2-2 island portion 212 adjacent to the 1-1 sub-connecting portion 311 may be cut off. Features regarding positions and conditions to which embodiments may be applied are the same as those described with reference to FIGS. 9A-10.

In an embodiment, the area of the 2-2 island portion 212 may be less than the area of other second island portions 21. Accordingly, the area or amount of a circuit that may be disposed in the 2-2 island portion 212 may be limited compared to other second island portions 21. The gate driving circuit GDC may include various drivers occupying different areas. Referring to FIG. 6B, a driver for providing the first scan signal GW may occupy a smaller area than a driver for providing the second scan signal GB or a driver for providing the third scan signal GI. Accordingly, in an embodiment, the driver for providing the first scan signal GW may be disposed in the 2-2 island portion 212.

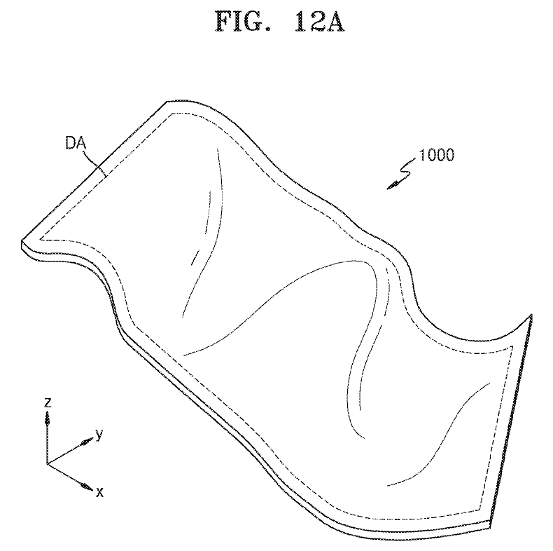

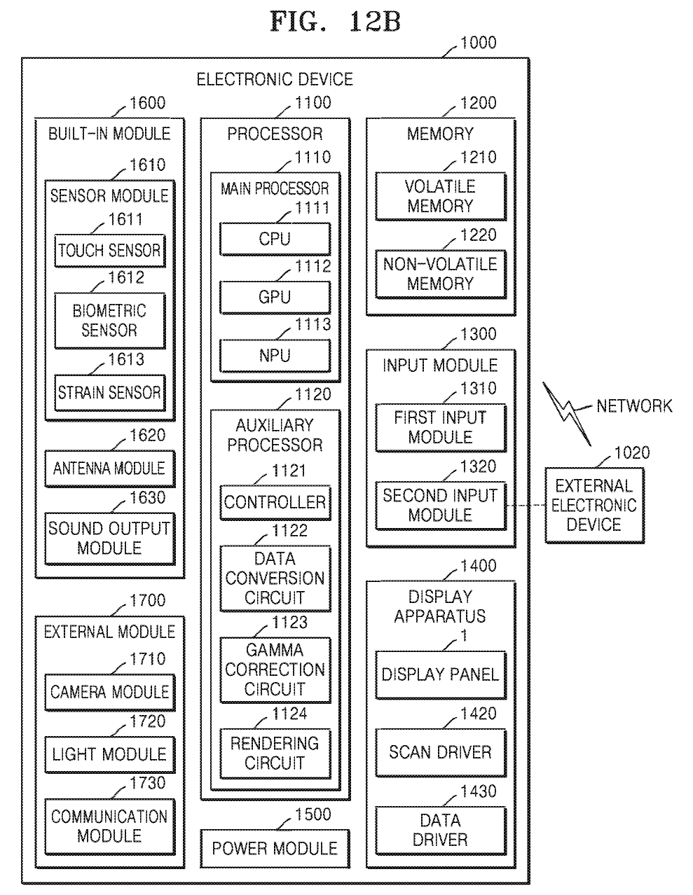

FIG. 12A is a perspective view schematically illustrating an electronic device including a display apparatus, according to an embodiment, and FIG. 12B is a block diagram schematically illustrating an electronic device including a display apparatus, according to an embodiment.

Referring to FIG. 12A, an embodiment of an electronic device 1000 may be freely deformed three-dimensionally and may provide a three-dimensional image surface through the display area DA. An operation in which the electronic device 1000 is freely deformed three-dimensionally is distinguished from an operation of an electronic device having a rollable display apparatus, such as an operation in which a part of a display area that was rolled up is visible to a user and then another part of the rolled display area is unfolded, thereby making the entire display area visible to the user (or an operation in which the entire display area that was unfolded is visible to the user and then the display area is rolled up, thereby making only a part of the display area visible to the user). The electronic device 1000 according to embodiments of the present disclosure may be deformed so that the area of the display area DA is increased and then reduced again while the electronic device 1000 is deformed in the x direction, the y direction, and/or the z direction.

Referring to FIG. 12B, an embodiment of the electronic device 1000 may include a processor 1100, a memory 1200, an input module 1300, a display module 1400, a power supply module 1500, an internal module 1600, and an external module 1700. According to an embodiment, in the electronic device 1000, at least one of the above components may be omitted or one or more other components may be added. According to an embodiment, some of the above components (e.g., the internal module 1600) may be integrated into another component (e.g., the display module 1400).

The processor 1100 may control at least one other component (e.g., hardware or software component) of the electronic device 1000 connected to the processor 1100 by executing software and may perform various data processing or calculation. According to an embodiment, as at least part of data processing or calculation, the processor 1100 may store a command or data received from another component (e.g., the input module 1300, a sensor module 1610, or a communication module 1730) in a volatile memory 1210, may process the command or the data stored in the volatile memory 1210, and may store result data in a nonvolatile memory 1220.

The processor 1100 may include a main processor 1110 and an auxiliary processor 1120. The main processor 1110 may include at least one selected from a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing an artificial intelligence (AI) model, and the AI model may be generated through machine learning. The AI model may include a plurality of artificial neural network layers. The artificial neural network may be, but is not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof. The AI model may include a software structure, in addition or alternatively, to a hardware structure. Among the above processing units and processors, at least two may be integrated into one unit (e.g., a single chip) or each may be implemented as an independent unit (e.g., a plurality of chips).

The auxiliary processor 1120 may include a controller 1121. The controller 1121 may include an interface conversion circuit and a timing control circuit. The controller 1121 receives an image signal from the main processor 1110, converts a data format of the image signal to meet the interface specification with the display module 1400, and outputs image data. The controller 1121 ay output various control signals used for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, and may compensate for the image data so that an image is displayed at a desired luminance according to characteristics of the electronic device 1000 or a user’s settings, or may convert the image data to reduce power consumption or compensate for an afterimage. The gamma correction circuit 1123 may convert image data or a gamma reference voltage so that an image displayed on the electronic device 1000 has desired gamma characteristics. The rendering circuit 1124 may receive image data from the controller 1121, and may render the image data by considering a pixel arrangement of the display apparatus 1 applied to the electronic device 1000. At least one selected from the data conversion circuit 1122, the gamma correction circuit 1123, and the rendering circuit 1124 may be integrated into another component (e.g., the main processor 1110 or the controller 1121). In an embodiment, the auxiliary processor 1120 may be integrated into a data driver 1430.

The memory 1200 may store various data used by at least one component (e.g., the processor 1100 or the sensor module 1610) of the electronic device 1000, and input data or output data for commands related to the various data. The memory 1200 may include at least one selected from the voltage memory 1210 and the nonvolatile memory 1220.

The input module 1300 may receive a command or data to be used in a component (e.g., the processor 1100, the sensor module 1610, or a sound output module 1630) of the electronic device 1000 from the outside of the electronic device 1000 (e.g., the user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input means or a touch input means such as a button, a dome switch, a jog wheel, or a jog switch located on a rear surface or a side surface of the electronic device 1000. The touch input means may include a touchscreen layer of the display apparatus 1.

The second input module 1320 may be connected to various types of external electronic devices 2000 connected to the electronic device 1000 by wire or wirelessly. According to an embodiment, the second input module 1320 may include a high-definition multimedia interface (HDMI), a universal serial bus (USB) interface, an SD card interface, or an audio interface. The second input module 1320 may include a connector for physically connecting the electronic device 1000 to the external electronic device 2000, for example, an HDMI connector, a USB connector, an SD card connector, or an audio connector (e.g., a headphone connector). In response to the external electronic device 2000 being connected to the second input module 1320, the electronic device 1000 may perform appropriate control related to the connected external electronic device 2000.

The display module 1400 visually provides information to the user. The display module 1400 may include the display apparatus 1, a scan driver 1420, and the data driver 1430.

The display apparatus 1 displays (outputs) information processed by the electronic device 1000. The display apparatus 1 may display execution screen information of an application driven by the electronic device 1000 or user interface (UI) or graphical user interface (GUI) information according to the execution screen information.

The scan driver 1420 may be mounted as a driving chip on the display apparatus 1. Alternatively, the scan driver 1420 may be directly formed on the display apparatus 1. In an embodiment, for example, the scan driver 1420 may include an amorphous silicon TFT gate driver circuit (ASG), a low-temperature polycrystalline silicon (LTPS) TFT gate driver circuit, or an oxide semiconductor TFT gate driver circuit (OSG) built in the display apparatus 1. The scan driver 1420 receives a control signal from the controller 1121, and outputs scan signals to the display apparatus 1 in response to the control signal.

The display apparatus 1 may further include an emission control driver. The emission control driver outputs an emission control signal to the display apparatus 1 in response to a control signal received from the controller 1121. The emission control driver may be formed separately from the scan driver 1420 or may be integrated into the scan driver 1420.

The data driver 1430 receives a control signal from the controller 1121, converts image data into a data voltage that is an analog voltage in response to the control signal, and then outputs data voltages to the display apparatus 1.

The data driver 1430 may be integrated with some components of the auxiliary processor 1120. In an embodiment, for example, the data driver 1430 may be provided as a timing controller embedded driver integrated circuit (IC) including the controller 1121.

The data driver 1430 may be mounted as a driving chip on the display apparatus 1. Alternatively, the data driver 1430 may be directly formed on the display apparatus 1. In an embodiment where the scan driver 1420 and the data driver 1430 are directly formed in the display apparatus 1, the display apparatus 1 may be substantially the display module 1400.

The power supply module 1500 supplies power to components of the electronic device 1000. The power supply module 1500 may include a battery that charges a power supply voltage. Also, the power supply module 1500 may include a connection port, and the connection port may be included in the second input module 1320 to which an external charger for supplying power is connected to charge the battery. Alternatively, the power supply module 1500 may include a wireless power transmission/reception member to charge the battery in a wireless manner. The wireless power transmission/reception member may include a plurality of antenna radiators in the form of coils. The power module 1500 may include a power management integrated circuit (PMIC). The PMIC supplies optimized power to each of the components of the electronic device 1000.

The electronic device 1000 may further include the internal module 1600 and the external module 1700. The internal module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display apparatus 1 and a touch sensor driver. The sensor module 1610 may detect an input by the user’s body part or an input by a pen, and may generate an electrical signal or a data value corresponding to the input. The sensor module 1610 may include at least one selected from a touch sensor 1611, a biometric sensor 1612, and a strain sensor 1613.

The touch sensor 1611 may generate a data value corresponding to coordinate information of an input by the user’s body part (e.g., finger) or an input by a pen. The touch sensor 1611 may generate a capacitance change amount, a pressure change amount, or an electromagnetic change amount due to an input as a data value.

The biometric sensor 1512 may generate a data value for recognizing a user’s body part (e.g., fingerprint, iris, or face) or a data value corresponding to body information (e.g., blood pressure, moisture, heart rate, or body composition). The biometric sensor 1512 may use an optical method, an ultrasonic method, or a capacitive method.

The strain sensor 1613 may include a layer, a pattern, or wirings whose measurable physical quantity varies according to stretching of the display apparatus 1. In an embodiment, for example, the strain sensor 1613 may include a layer, a pattern, or wirings whose pressure, resistance and/or capacitance is changed by stretching of the display apparatus 1. In another embodiment, the strain sensor 1613 may include an optical layer or an optical pattern whose transmittance and/or reflectance is changed by stretching of the display apparatus 1.

The electronic device 1000 may improve the quality of an image displayed on the display apparatus 1 or control the display apparatus 1 based on a change in a physical quantity according to stretching of the display apparatus 1 measured by the strain sensor 1613. A control operation of the display apparatus 1 may include, for example, an operation of displaying an operation image for protecting the display apparatus 1, blocking a voltage for driving the display apparatus 1, or stopping a stretching operation of the display apparatus 1.

In an embodiment, at least one selected from the touch sensor 1611, the biometric sensor 1612, and the strain sensor 1613 may be embedded in the display apparatus 1. In an embodiment, for example, at least one selected from the touch sensor 1611, the biometric sensor 1612, and the strain sensor 1613 may be formed through a continuous process with a process of forming a pixel driving circuit unit and a light-emitting element of the display apparatus 1. Accordingly, the display apparatus 1 may function as one of the input modules 1300 that provide an input interface between the electronic device 1000 and the user and may also function as one of the display modules 1400 that provide an output interface between the electronic device 1000 and the user.

In another embodiment, at least two selected from the touch sensor 1611, the biometric sensor 1612, and the strain sensor 1613 may be integrated into one sensing panel through the same process. In an embodiment, the sensing panel may be disposed between the display apparatus 1 and a window cover disposed on a front surface of the display apparatus 1, but the present disclosure is not limited thereto.

The antenna module 1620 may include one or more antennas for transmitting a signal or power to the outside or receiving a signal or power from the outside. According to an embodiment, the communication module 1730 may transmit a signal to an external electronic device or may receive a signal from an external electronic device through an antenna suitable for a communication method. An antenna pattern of the antenna module 1620 may be integrated into one component (e.g., the display apparatus 1) of the display module 1400 or the input sensor 1612.

The sound output module 1630 is a device for outputting a sound signal to the outside of the electronic device 1000 and may output sound data received from the communication module 1730 or stored in the memory 1200 in a call signal reception mode, a call mode or a recording mode, a voice recognition mode, or a broadcast reception mode. The sound output module 1630 may output a sound signal related to a function (e.g., a call signal reception sound or a message reception sound) performed in the electronic device 1000. The sound output module 1630 may include a receiver and a speaker. At least one selected from the receiver and the speaker may be a sound generating device that is attached to a rear surface of the display apparatus 1 and outputs sound by vibrating the display apparatus 1. The sound generating device may be a piezoelectric element or a piezoelectric actuator that contracts or expands in response to an electrical signal, or an exciter that generates a magnetic force by using a voice coil and vibrates the display apparatus 1.

The camera module 1710 may capture a still image and a moving image. According to an embodiment, the camera module 1710 may include one or more lenses, an image sensor, or an image signal processor. The camera module 1710 may further include an infrared camera for measuring the presence or absence of the user, a location of the user, and a gaze of the user.

The light module 1720 may output a signal for notifying the occurrence of an event by using light of a light source, or may provide light for obtaining an image. Examples of the event may include message reception, call signal reception, missing call, alarm, schedule notification, email reception, and battery charging capacity information notification. The light module 1720 may include a light-emitting diode or a xenon-lamp. The light module 1720 may emit light of a single color or multiple colors to a front surface or a rear surface of the electronic device 1000. The light module 1720 may interoperate with the camera module 1710 or may independently operate.

The communication module 1730 may support establishing a wired or wireless communication channel between the electronic device 1000 and the external electronic device 2000 and performing communication through the established communication channel. The communication module 1730 may include one or both of a wireless communication module such as a cellular communication module, a short-range wireless communication module, or a global navigation satellite system (GNSS) communication module and a wired communication module such as a local area network (LAN) communication module or a power line communication module. The communication module 1730 may transmit and receive a wireless signal on the Internet by using at least one of wireless LAN (WLAN), wireless-fidelity (Wi-Fi), Wi-Fi direct, and digital living network alliance (DLNA). Also, the communication module 1730 may support short-range communication by using at least one selected from Bluetooth™, radio frequency identification (RFID), infrared data association (IrDA), ultra-wideband (UWB), ZigBee, near-field communication (NFC), Wi-Fi, Wi-Fi direct, and wireless universal serial bus (USB). The various types of communication modules 1730 described above may be implemented as one chip or may be implemented as separate chips.

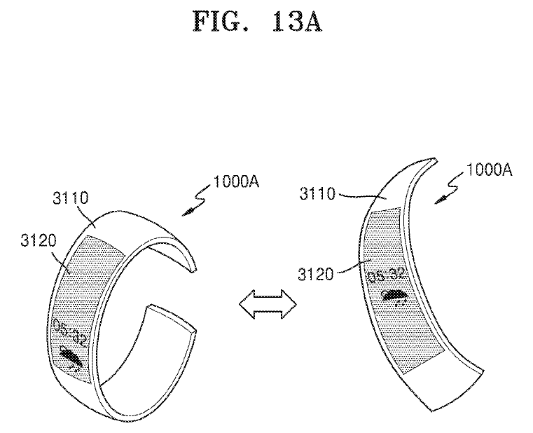

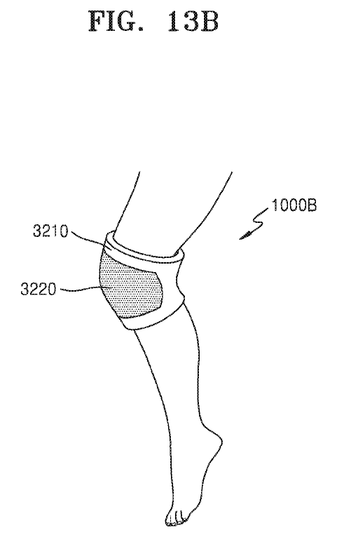

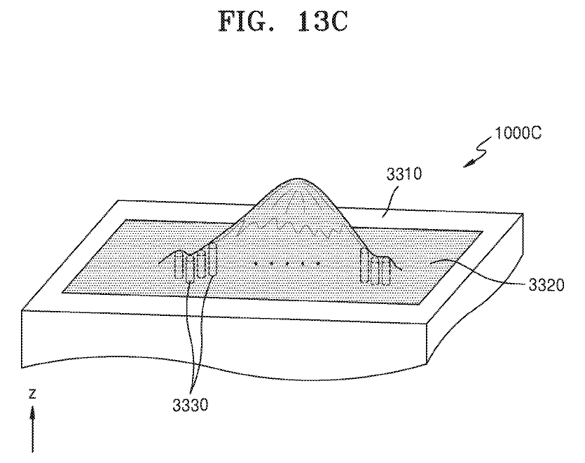

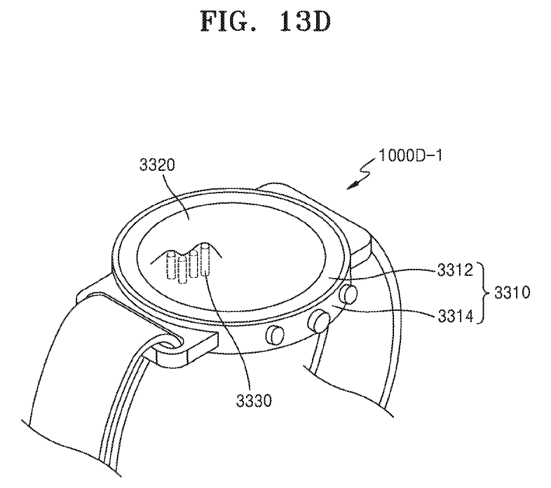

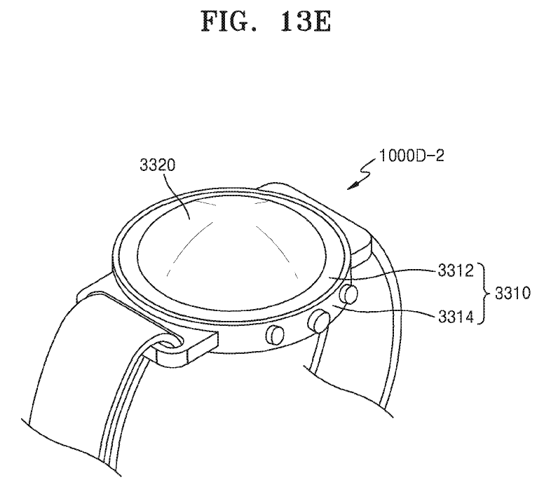

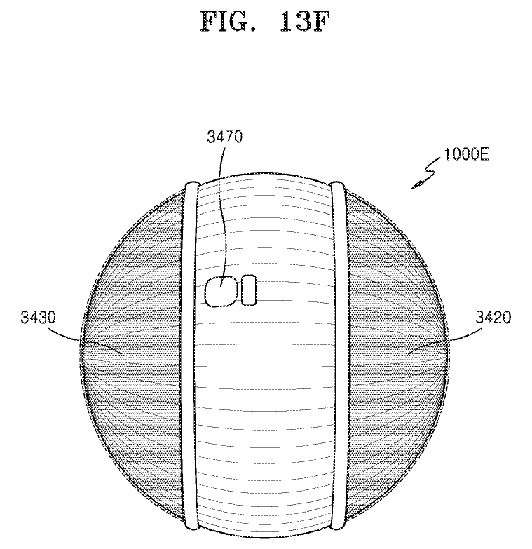

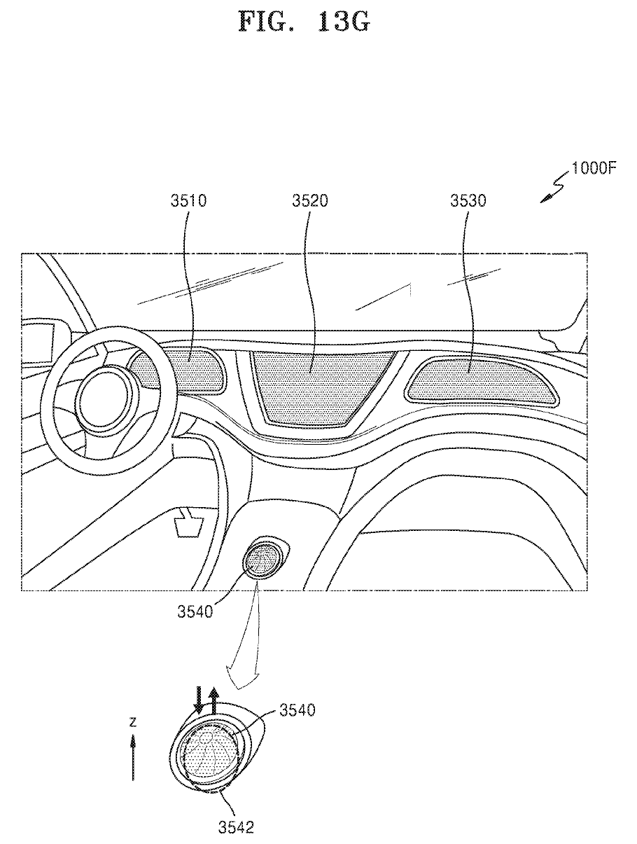

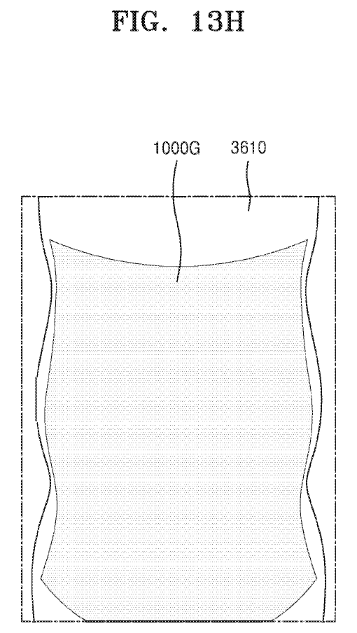

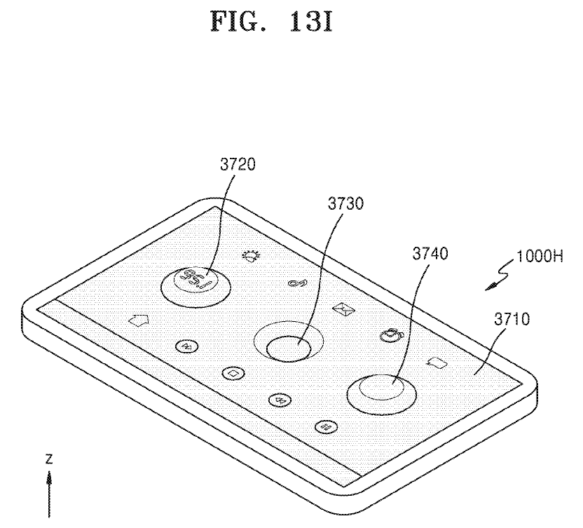

FIGS. 13A-13I are perspective views schematically illustrating embodiments of an electronic device including a display apparatus, according to an embodiment.

Referring to FIG. 13A, a display apparatus according to an embodiment may be used in a wearable electronic device 1000A that may be worn on a user’s body part. The wearable electronic device 1000A may include a body portion 3110 and a display unit 3120 provided on the body portion 3110. A display apparatus according to embodiments of the present disclosure may be used as the display unit 3120 of the wearable electronic device 1000A. As shown in FIG. 13A, the wearable electronic device 1000A may be deformable. In an embodiment, the wearable electronic device 1000A may be used as a smartwatch or a smartphone according to the user’s selection.

FIG. 13B illustrates an embodiment where the wearable electronic device 1000A is a medical electronic device 1000B. In an embodiment, the medical electronic device 1000B may include a body portion 3210 and a light-emitting unit 3220. A display apparatus according to embodiments of the present disclosure may be used as the light-emitting unit 3220 of the medical electronic device 1000B. The light-emitting unit 3220 may emit light of a certain wavelength band (e.g., infrared light or visible light) to a patient’s body. In an embodiment, the body portion 3210 may include a stretchable fiber material, and may have a structure that may be worn on a user’s body.

FIG. 13C illustrates an embodiment where the wearable electronic device 1000A is an educational electronic device 1000C. In an embodiment, the educational electronic device may include a display unit 3320 provided in a body portion 3310. The display unit 3320 may use a display apparatus according to embodiments of the present disclosure. An image such as a sea with waves, a snow-covered mountain, or a volcano through which lava flows may be provided through the display unit 3320, and in this case, the display unit 3320 may be stretched in a height direction (e.g., the z direction) by reflecting the height of the waves, mountain, or volcano. In some embodiments, a part of the display unit 3320 may be sequentially changed in height along a direction in which the lava flows to three-dimensionally show the movement of the lava. The educational electronic device 1000C may include a plurality of pins (or strokes) 3330 disposed on a rear surface of the display unit 3320 so that the display unit 3320 is stretched in the height direction. As the pins 3330 move along the third direction (e.g., the +z direction or the -z direction), an image displayed on the display unit 3320 may be implemented to have a three-dimensional height. Although an embodiment where the wearable electronic device 1000A is the educational electronic device 1000C is described with reference to FIG. 13C, its use is not limited as long as certain image information is provided.

FIGS. 13D and 13E illustrate the use of a display apparatus in wearable electronic devices 1000D-1 and 1000D-2 such as smart watches.

In an embodiment, because a display apparatus corresponding to the display unit 3320 of the electronic device 1000D-1 is three-dimensionally stretchable as shown in FIG. 13D, various haptic information in addition to visual information through an image may be provided to the user. In an embodiment, the electronic device 1000D-1 may provide haptic information such as Braille display for the visually impaired or tactile stimulation linked to an image by using the plurality of pins (or strokes) 3330 disposed under the display unit 3320. The display apparatus corresponding to the display unit 3320 is three-dimensionally stretchable and thus may provide the haptic information. The electronic device 1000D-1 may include the body portion 3310 including a housing 3314 in which the display apparatus for forming the display unit 3320 and the pins (or strokes) 3330 are accommodated and a frame 3312 that may be coupled to the housing 3314 with the display apparatus therebetween. In some embodiments, the frame 3312 may be integrally formed with the housing 3314 as a single unitary indivisible part.

The electronic device 1000D-2 of FIG. 13E may include the body portion 3310 and the display unit 3320 that is accommodated in the body portion 3310 and may provide visual information, like in FIG. 13D. In some embodiments, because the display apparatus corresponding to the display unit 3320 is three-dimensionally stretchable, the display apparatus may include the display unit 3320 having a dome shape. In an embodiment, the display apparatus may be assembled on a dome-shaped body frame in a process of manufacturing the electronic device 1000D-2, and in this case, the display apparatus is three-dimensionally stretchable, and thus may be assembled while being stretched along a shape of the hemispherical body frame.

FIG. 13F illustrates an embodiment where an electronic device 1000E is a robot. The robot may recognize movement or an object by using a camera module 3470, and may display a certain image to a user through display units 3420 and 3430.

In some embodiments, because display apparatuses according to an embodiment may be stretched in various directions as described above, the display apparatuses may be assembled to a body frame having a hemispherical shape, and thus, the robot may include the display units 3420 and 3430 each having a hemispherical shape.

FIG. 13G illustrates a display device 1000F for a vehicle as an electronic device, according to an embodiment of the present disclosure. The display device 1000F for a vehicle may include a cluster 3510, a center information display (CID) 3520, and/or a co-driver display 3530. Because a display apparatus according to an embodiment of the present disclosure may be stretched in various directions, the display apparatus may be used in the cluster 3510, the CID 3520, and/or the co-driver display 3530 regardless of a shape of an internal frame of a vehicle.

Although the cluster 3510, the CID 3520, and/or the co-driver display 3530 are separated from each other in FIG. 13G, the present disclosure is not limited thereto. In another embodiment, two or more selected from the cluster 3510, the CID 3520, and the co-driver display 3530 may be integrally connected.

In some embodiments, the display device 1000F for a vehicle may include a button 3540 for displaying a certain image. Referring to an enlarged view of FIG. 13G, the button 3540 having a hemispherical shape may include an object 3542 that provides a feeling of using the button while moving in the +z direction or the -z direction, and a display apparatus disposed on the object 3542. In some embodiments, where the object 3542 has a three-dimensional rounded surface, the display apparatus may also have a three-dimensional rounded surface.

FIG. 13H illustrates an electronic device 1000G for advertisement or exhibition as an electronic device, according to an embodiment. In some embodiments, the electronic device 1000G for advertisement or exhibition may be installed on a fixed structure 3610 such as a wall or a pillar. In an embodiment where the structure 3610 includes an uneven surface as shown in FIG. 13H, the electronic device 1000G for advertisement or exhibition may be disposed along the uneven surface of the structure 3610. In some embodiments, the electronic device 1000G for advertisement or exhibition may be installed on the structure 3610 by using a heat shrink film or the like.

FIG. 13I illustrates that an electronic device 1000H is a controller, according to an embodiment. The controller may include an image-type button. In an embodiment, for example, a display unit 3710 of the controller may include first to third button areas 3720, 3730, and 3740 protruding in the +z direction or protruding in the -z direction (or recessed in the z direction). In some embodiments, the first and third button areas 3720 and 3740 may protrude in the z direction, and the second button area 3730 may protrude in the -z direction (or be recessed in the z direction).

According to embodiments of the present disclosure, a display apparatus that may display a high-quality image and is stretchable may be provided. The effects described above are examples, and the effects of the present disclosure are not limited thereto.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus in which a display area and a non-display area at least partially surrounding the display area are defined, the display apparatus comprising:
a first row comprising a first first island portion of the display area, a first connecting portion, and a first second island portion of the non-display area, which are arranged in a first direction; and
a second row disposed on a side of the first row in a second direction intersecting the first direction, the second row comprising a second first island portion of the display area, a second connecting portion, and a second second island portion of the non-display area, which are arranged in the first direction,
wherein, the first connecting portion and the second second island portion overlap each other in the second direction,
wherein the first connecting portion has a shape inverted from a shape of the second connecting portion with respect to an axis of symmetry in the first direction.

2. The display apparatus of claim 1, wherein the display area has a curved periphery.

3. The display apparatus of claim 1, wherein
one end of the first connecting portion is connected to the first first island portion, and an opposing end of the first connecting portion is connected to the first second island portion, and
one end of the second connecting portion is connected to the second first island portion, and an opposing end of the second connecting portion is connected to the second second island portion.

4. The display apparatus of claim 3, wherein the first connecting portion comprises a first first sub-connecting portion connected to the first second island portion, and a plurality of second first sub-connecting portions connected to the first first sub-connecting portion and the first first island portion.

5. The display apparatus of claim 4, wherein, the first first sub-connecting portion and the second second island portion overlap each other in the second direction.

6. The display apparatus of claim 1, wherein the first connecting portion and the second connecting portion are disposed in the non-display area.

7. The display apparatus of claim 1, wherein each of the first connecting portion and the second connecting portion has a serpentine shape.

8. The display apparatus of claim 1, wherein
the first first island portion and the second first island portion have a same shape as each other, and
the first second island portion and the second second island portion have a same shape as each other,
wherein the first first island portion, the second first island portion, the first second island portion, and the second second island portion are rotated by a same angle, about a rotational axis in a third direction intersecting the first direction and the second direction.

9. The display apparatus of claim 1, further comprising:
a first bridge portion connecting the first first island portion to the second first island portion; and
a second bridge portion connecting the first second island portion to the second second island portion.

10. The display apparatus of claim 1, wherein
the first connecting portion is connected to one surface of the first second island portion, and
the second connecting portion is connected to one surface of the second second island portion extending in a direction different from the one surface of the first second island portion to which the first connecting portion is connected.

11. A display apparatus in which a display area and a non-display area at least partially surrounding the display area are defined, the display apparatus comprising:
a first row comprising a first first island portion of the display area, a first connecting portion, and a first second island portion of the non-display area, which are arranged in a first direction; and
a second row disposed on a side of the first row in a second direction intersecting the first direction, the second row comprising a second first island portion of the display area, a second connecting portion, and a second second island portion of the non-display area, which are arranged in the first direction,
wherein, the first connecting portion and the second second island portion overlap each other in the second direction,
wherein an area of the second second island portion is less than an area of the first second island portion.

12. The display apparatus of claim 11, wherein the display area has a curved periphery.

13. The display apparatus of claim 11, wherein
one end of the first connecting portion is connected to the first first island portion, and an opposing end of the first connecting portion is connected to the first second island portion, and
one end of the second connecting portion is connected to the second first island portion, and an opposing end of the second connecting portion is connected to the second second island portion.

14. The display apparatus of claim 11, wherein the first connecting portion and the second connecting portion have a same shape as each other.

15. The display apparatus of claim 11, wherein the area of the second second island portion is in a range from about 50% to about 90% of the area of the first second island portion.

16. An electronic device comprising a display unit, the electronic device comprising:
a display apparatus corresponding to the display unit, wherein a display area and a non-display area at least partially surrounding the display area are defined in the display apparatus; and
strokes disposed under the display apparatus and moving in a vertical direction,
wherein the display apparatus comprises:
a first row comprising a first first island portion of the display area, a first connecting portion, and a first second island portion of the non-display area, which are arranged in a first direction; and
a second row disposed on a side of the first row in a second direction intersecting the first direction, the second row comprising a second first island portion of the display area, a second connecting portion, and a second second island portion of the non-display area, which are arranged in the first direction,
wherein, the first connecting portion and the second second island portion overlap each other in the second direction,
wherein the first connecting portion has a shape inverted from a shape of the second connecting portion with respect to an axis of symmetry in the first direction.

17. The electronic device of claim 16, further comprising a frame in which the display apparatus and the strokes are accommodated.

18. The electronic device of claim 16, wherein the electronic device comprises a wearable electronic device.

19. The electronic device of claim 16, wherein the display apparatus is three-dimensionally stretchable by the strokes.

20. The electronic device of claim 16, wherein the display unit has a dome shape in a state where the display apparatus is not three-dimensionally stretched.
